(19) United States
(12) Patent Application Publication
(10) Pub. No.: US 2001/0033347 A1
(43) Pub. Date: Oct. 25, 2001

(54) Display element and layered type display element

(75) Inventors: Takeshi Kitahora, Osaka-Shi (JP); Hideaki Ueda, Kishiwada-Shi (JP)

Correspondence Address: SIDLEY AUSTIN BROWN & WOOD, 717 NORTH HARWOOD, SUITE 3400, DALLAS, TX, 75201, US

(73) Assignee: Minolta Co., Ltd.

(21) Appl. No.: 09/812,119

(22) Filed: Mar. 16, 2001

(30) Foreign Application Priority Data
Mar. 17, 2000 (JP) 2000-76126

(51) Int. Cl. G02F 1/1333

(52) U.S. Cl. 349/58

(57) ABSTRACT

A display element or a layered type display element having a resin substrate for holding or carrying a display layer.

In an aspect of the invention, a gas barrier layer made of SiOₓ (0<x≦2) or Al₂O₃, and a transparent electrode made of IZO, i.e., an amorphous oxide comprising In, Zn and O as essential constituent elements are formed on one surface of the substrate in this order from the substrate side; and an anchor layer is formed between the substrate and the gas barrier layer.

In another aspect, a gas barrier layer made of SiOₓ or Al₂O₃ is formed on one surface of the substrate; and a transparent electrode made of IZO is formed on another surface of the substrate.

In a further aspect, a gas barrier layer made of SiOₓ or Al₂O₃ and a transparent electrode made of IZO are formed on one surface of the substrate in this order from the substrate side; and a hard coat layer is formed on another surface of the substrate.

In a further aspect, a gas barrier layer made of SiOₓ or Al₂O₃, and a hard coat layer are formed on one surface of the substrate in this order from the substrate side; and a transparent electrode made of IZO is formed on another surface of the substrate.

This application is based on a patent application No. 2000-76126 filed in Japan, the contents of which are hereby incorporated by reference.

### BACKGROUND OF THE INVENTION

1. Field of the Invention

The present invention relates to a display element having a display layer for performing display, such as a liquid crystal layer, an organic luminescent film or others, and a substrate for holding or carrying the display layer.

This invention also relates to a layered type display element having a plurality of display layers layered together, and a substrate for holding or carrying the display layer.

2. Description of Related Art

In recent years, a liquid crystal display (LCD) having a liquid crystal element is increasingly employed as a monitor for a computer or television instead of a CRT display. An electro-luminescence display device having an electro-luminescence element as well as a plasma display panel (PDP) are drawing attention as the next generation of display device.

Generally in a liquid crystal element, a liquid crystal is held between a pair of substrates, and an electrode is provided on each of the substrates for applying a voltage across the liquid crystal. Generally in an organic electro-luminescence element (organic EL element), an organic luminescent film is carried on a substrate, and electrodes are arranged on both sides of the organic luminescent film for applying a voltage across the organic luminescent film.

A glass substrate has been usually employed as the substrate of the liquid crystal element or the organic EL element. However, recently a resin film or a resin sheet is sometimes employed as the substrate for reducing the thickness or the weight of the element.

ITO is often used as a material for the electrode.

However, the resin substrate, when used in the liquid crystal element or organic EL element, is more likely to pass water and oxygen (O₂) therethrough than the glass substrate so that the liquid crystal, organic luminescent film, electrode and others would be readily deteriorated due to water and/or oxygen.

The resin substrate is susceptible to be marred or scratched during, e.g., the production of the element.

When the ITO electrode is formed on the resin substrate, the electrode may readily become cracked or damaged due to the brittleness of ITO in the production of the element, consequently making it difficult to produce the element in a high yield.

Such problem may arise not only in the liquid crystal element and organic EL element but also in a layered type liquid crystal element having a plurality of liquid crystal layers layered together as well as a layered type organic EL elements (overlay type organic EL elements) having a plurality of organic luminescent films layered together. Similar problem may arise in a display element having a display layer for performing display, such as the liquid crystal layer, organic luminescent film or others, as well as in a layered type display element having a plurality of display layers layered together.

### SUMMARY OF THE INVENTION

An object of the present invention is to provide a display element having a resin substrate for holding or carrying a display layer, and more particularly to provide the display element which has at least one of the advantages described below in (a1) to (a3):

(a1) a deterioration of the display layer and others due to water and oxygen can be suppressed;

(a2) a marring of the resin substrate can be suppressed; and

(a3) a damage of an electrode formed on the resin substrate can be suppressed so that the element can be produced in a higher yield.

Another object of the present invention is to provide a layered type display element having a plurality of display layers layered together, and a resin substrate for holding or carrying the display layer, and more particularly to provide the layered type display element which has at least one of the advantages given below in (b1) to (b3):

(b1) a deterioration of the display layer and others due to water and oxygen can be suppressed;

(b2) a marring of the resin substrate can be suppressed; and

(b3) a damage of an electrode formed on the resin substrate can be suppressed so that the element can be produced in a higher yield.

A further object of the present invention is to provide a liquid crystal element having a resin substrate for holding a liquid crystal layer, and more particularly to provide the liquid crystal element which has at least one of the advantages described below in (c1) to (c3):

(c1) a deterioration of the liquid crystal layer and others due to water and oxygen can be suppressed;

(c2) a marring of the resin substrate can be suppressed; and

(c3) a damage of an electrode formed on the resin substrate can be suppressed so that the element can be produced in a higher yield.

A still further object of the present invention is to provide a layered type liquid crystal element having a plurality of liquid crystal layers layered together, and a resin substrate for holding the liquid crystal layer, and more particularly to provide the layered type liquid crystal element which has at least one of the advantages described below in (d1) to (d3):

(d1) a deterioration of the liquid crystal layer and others due to water and oxygen can be suppressed;

(d2) a marring of the resin substrate can be suppressed; and

(d3) a damage of an electrode formed on the resin substrate can be suppressed so that the element can be produced in a higher yield.

A still further object of the present invention is to provide an electro-luminescence element having a resin substrate for holding or carrying an organic luminescent film, and more particularly to provide the electro-luminescence element which has at least one of the advantages described below in (e1) to (e3):

(e1) a deterioration of the organic luminescent film and others due to water and oxygen can be suppressed;

(e2) a marring of the resin substrate can be suppressed; and

(e3) a damage of an electrode formed on the resin substrate can be suppressed so that the element can be produced in a higher yield.

A still further object of the present invention is to provide a layered type organic electro-luminescence element (overlay type organic EL element) having a plurality of organic luminescent films layered together, and a resin substrate for holding or carrying the organic luminescent film, and more particularly to provide the layered type organic electro-luminescence element which has at least one of the advantages described below in (f1) to (f3):

(f1) a deterioration of the organic luminescent film and others due to water and oxygen can be suppressed;

(f2) a marring of the resin substrate can be suppressed; and

(f3) a damage of an electrode formed on the resin substrate can be suppressed so that the element can be produced in a higher yield.

The present invention provides a display element having a resin substrate for holding or carrying a display layer, and more particularly as described below.

The present invention also provides a layered type display element having a plurality of display layers layered together and a resin substrate for holding or carrying the display layer, and more particularly as described below.

In an aspect of the invention, on the resin substrate, an anchor layer, a gas barrier layer made of SiOₓ (0<x≦2) or Al₂O₃, and a transparent electrode made of an amorphous oxide comprising indium (In), zinc (Zn) and oxygen (O) as essential constituent elements are formed in this order.

In another aspect of the invention, on a first surface of the resin substrate, a gas barrier layer made of SiOₓ (0<x≦2) or Al₂O₃ is formed, while, on a second surface of the resin substrate that is opposite of the first surface, a transparent electrode made of an amorphous oxide comprising indium (In), zinc (Zn) and oxygen (O) as essential constituent elements is formed.

In another aspect of the invention, on a first surface of the resin substrate, a gas barrier layer made of SiOₓ (0<x≦2) or Al₂O₃ and a transparent electrode made of an amorphous oxide comprising indium (In), zinc (Zn) and oxygen (O) as essential constituent elements are formed in this order, while, on a second surface of the resin substrate that is opposite of the first surface, a hard coat layer is formed.

In a still further aspect of the invention, on a first surface of the resin substrate, a gas barrier layer made of SiOₓ (0<x≦2) or Al₂O₃ and a hard coat layer are formed in this order, while, on a second surface of the resin substrate that is opposite of the first surface, a transparent electrode made of an amorphous oxide comprising indium (In), zinc (Zn) and oxygen (O) as essential constituent elements is formed.

The foregoing and other objects, features, aspects and advantages of the present invention will become more apparent from the following detailed description and the accompanying drawings.

### BRIEF DESCRIPTION OF THE DRAWINGS

FIG. 1 is a schematic section view showing an example of the liquid crystal element according to the present invention.

FIG. 2 is a schematic section view showing another example of the liquid crystal element according to the present invention.

FIG. 3 is a schematic section view showing a further example of the liquid crystal element according to the present invention.

FIG. 4 is a schematic section view showing a still further example of the liquid crystal element according to the present invention.

FIG. 5 is a schematic section view showing further another example of the liquid crystal element according to the present invention.

FIG. 6 is a schematic section view showing an example of the layered type liquid crystal element according to the present invention.

FIG. 7 is a schematic section view showing another example of the layered type liquid crystal element according to the present invention.

FIG. 8 is a schematic section view showing a further example of the liquid crystal element according to the present invention.

FIG. 9 shows an example of a fixing device.

FIG. 10 shows an example of a display drive control device of the liquid crystal element (liquid crystal cell).

FIG. 11 is a schematic section view showing an example of the organic electro-luminescence element according to the present invention.

FIG. 12 is a schematic section view showing another example of the organic electro-luminescence element according to the present invention.

FIG. 13 is a schematic section view showing an example of the layered type organic electro-luminescence element (overlay type organic EL element) according to the present invention.

FIGS. 14 (A) to (G) are schematic section views showing the substrate modules all used in the experimental examples.

### DESCRIPTION OF THE PREFERRED EMBODIMENTS

[1] Described below are display elements, liquid crystal elements, organic electro-luminescence elements (organic EL elements), layered type display elements, layered type liquid crystal elements and layered type organic electro-luminescence elements (overlay type organic EL elements) reflecting at least one aspect of the present invention.

### [1-1] DISPLAY ELEMENT

In the following embodiments, four types of display elements (first to fourth types of display elements) are presented.

In any type of display elements (single layered display elements) according to the following embodiments, a display layer is provided for performing display.

The display layer is provided for changing its state by applying a voltage or otherwise. That is, the state of the display layer can be changed by applying a voltage or otherwise. For example, a light transmittance of the display layer or a reflective index thereof can be changed by application of a voltage or otherwise, or a luminous state of the display layer can be changed by application of a voltage or otherwise.

The display layer may be a light-controlling layer for controlling, e.g. the reflection of incident light or the transmission thereof. The light-controlling layer may be, for example, a liquid crystal layer containing a liquid crystal to be used in a liquid crystal element. Stated more specifically, when the display layer is the liquid crystal layer in any type of display elements according to the following embodiments, the display element can be used as the liquid crystal element.

The display layer may be, for example, a self-luminous layer. The self-luminous layer may be an organic luminescent film to be used in an organic electro-luminescence element or an inorganic luminescent film to be used in an inorganic electro-luminescence element. In other words, if the display layer is the organic luminescent film in any type of display elements according to the following embodiments, the display element can be used as the organic luminescence element (organic EL element). Further, if the display layer is the inorganic luminescent film in any type of display elements according to the following embodiments, the display element can be used as the inorganic luminescence element (inorganic EL element).

In any type of display elements according to the following embodiments, the display layer is held between a pair of substrates or is carried (supported) on one substrate. In other words, any type of display elements according to the following embodiments has at least one substrate for holding or carrying the display layer. If the display layer is, for example, the liquid crystal layer, the liquid crystal layer (display layer) may be typically held between a pair of substrates. If the display layer is, for example, the organic luminescent film, the organic luminescent film (display layer) may be held between a pair of substrates or carried on one substrate.

In any type of display elements according to the following embodiments, a substrate made of resin (i.e. resin substrate) is used as the substrate for holding or carrying the display layer. If two or more substrates are used in any type of display elements according to the following embodiments, at least one of the substrates may be the resin substrate.

In any type of display elements according to the following embodiments, a plurality of layers including an electrode (electrode layer) are formed on the resin substrate for holding or carrying the display layer.

When it is stated in the following description that a first layer is formed on the substrate, another layer may be formed between the substrate and the first layer, and/or another layer may be formed on the first layer. Further when it is stated that a first layer and a second layer are formed on the substrate in this order, another layer may be formed between the first layer and the substrate, another layer may be formed between the first layer and the second layer, and/or another layer may be formed on the second layer. When it is stated that three or more layers are formed on the substrate, the same is meant. Similarly, in generic, when it is stated that layer A is formed on layer B, another layer may be formed between the layers A and B unless otherwise provided.

In any type of display elements according to the following embodiments, features reside in the layer(s) formed on the resin substrate for holding or carrying the display layer, in the layer structure and others. The first to fourth types of display elements according to the following embodiments differ from each other in the layers formed on the resin substrate and in the layer structure.

### [1-2] LAYERED TYPE DISPLAY ELEMENT

In the following embodiments, four types of layered type display elements (first to fourth types of layered type display elements) in each of which a plurality of display layers are layered together are also presented.

In any type of layered type display elements according to the following embodiments, the plural display layers may be identical in kind with each other, or at least one of the display layers may be different in kind from the other. In any type of layered type display elements according to the following embodiments, if all of the plurality of display layers are the liquid crystal layers each including the liquid crystal, the layered type display element can be used as a layered type liquid crystal element. In any type of layered type display elements according to the following embodiments, if all of the plurality of display layers are the organic luminescent films, the layered type display element can be used as a layered type organic luminescence element (overlay type organic EL element). In any type of layered type display elements according to the following embodiments, at least one of plural display layers may be the liquid crystal layer, and at least one of the remaining display layers may be the organic luminescent film.

In any type of layered type display elements according to the following embodiments, each display layer is held between a pair of substrates or is carried on one substrate, similar to the single layered display elements of the following embodiments. In any type of layered type display elements according to the following embodiments, one or more display layer(s) among the plural display layers may be each held between a pair of substrates, and one or more remaining display layer(s) may be each carried on one substrate. In any type of layered type display elements according to the following embodiments, the substrate used for holding or carrying one of plural display layers may be utilized for holding or carrying the other display layer.

In either case, any type of layered type display elements according to the following embodiments has a plurality of substrates for holding or carrying a plurality of display layers. In any type of layered type display elements according to the following embodiments, a resin substrate is employed as the substrate for holding or carrying the display layer. In any type of layered type display elements according to the following embodiments, at least one of the substrates may be the resin substrate.

In any type of layered type display elements according to the following embodiments, a plurality of layers including an electrode are formed on the resin substrate for holding or carrying the display layer.

In any type of layered type display elements according to the following embodiments, features reside in the layer(s) formed on the resin substrate for holding or carrying the display layer, in the layer structure and others. The first to fourth types of layered display elements according to the following embodiments differ from each other in the layers formed on the resin substrate and in the layer structure.

The layers formed on the resin substrate and the layer structure in the first to fourth types of layered type display elements according to the following embodiments are the same as those in the first to fourth types of single layered display elements according to the following embodiments, respectively.

Any type of the first to fourth types of layered type display elements according to the following embodiments may have three display layers, i.e., a display layer for red display, a display layer for green display and a display layer for blue display, layered together for performing multicolor display.

### [1-3] LIQUID CRYSTAL ELEMENT

In the following embodiments, four types of liquid crystal elements (first to fourth types of liquid crystal elements) are presented.

Any type of liquid crystal elements (single layered liquid crystal elements) according to the following embodiments has a liquid crystal layer containing a liquid crystal.

In any type of liquid crystal elements according to the following embodiments, the liquid crystal layer is held between a pair of substrates. That is, any type of liquid crystal elements according to the following embodiments has a pair of substrates for holding the liquid crystal layer therebetween.

In any type of liquid crystal elements according to the following embodiments, a resin substrate is employed as the substrate for holding the liquid crystal layer. In any type of liquid crystal elements according to the following embodiments, at least one of the paired substrates may be the resin substrate.

In any type of liquid crystal elements according to the following embodiments, a plurality of layers including an electrode are formed on the resin substrate for holding the display layer.

In any type of liquid crystal elements according to the following embodiments, features reside in the layer(s) formed on the resin substrate for holding the display layer, in the layer structure and others.

The first to fourth types of liquid crystal elements according to the following embodiments differ from each other in the layers formed on the resin substrate and the layer structure.

The layers formed on the resin substrate and the layer structure in the first to fourth types of liquid crystal elements according to the following embodiments are the same as those in the first to fourth types of single layered display elements according to the following embodiments, respectively.

### [1-4] LAYERED TYPE LIQUID CRYSTAL ELEMENT

In the following embodiments, four types of layered type liquid crystal elements (first to fourth types of layered type liquid crystal elements) in each of which a plurality of liquid crystal layers are layered together are also presented.

In any type of layered type liquid crystal elements according to the following embodiments, a plurality of liquid crystal layers are each held between a pair of substrates. In any type of layered type liquid crystal elements according to the following embodiments, the substrate used for holding one liquid crystal layer among a plurality of liquid crystal layers may be utilized for holding the other liquid crystal layer.

In any type of layered type liquid crystal elements according to the following embodiments, a plurality of substrates are provided for holding a plurality of liquid crystal layers. In any type of layered type liquid crystal elements according to the following embodiments, a resin substrate is employed as the substrate for holding the liquid crystal layer. In any type of layered type liquid crystal elements according to the following embodiments, at least one of the plural substrates may be the resin substrate.

In any type of layered type liquid crystal elements according to the following embodiments, a plurality of layers including an electrode are formed on the resin substrate for holding the display layer, similar to the single layered liquid crystal elements of the following embodiments.

In any type of layered type liquid crystal elements according to the following embodiments, features reside in the layer(s) formed on the resin substrate for holding the liquid crystal layer, in the layer structure and others. The first to fourth types of layered type liquid crystal elements according to the following embodiments differ from each other in the layers formed on the resin substrate and the layer structure.

The layers formed on the resin substrate and the layer structure in the first to fourth types of layered type liquid crystal elements according to the following embodiments are the same as those in the first to fourth types of display elements according to the following embodiments, respectively.

Any of the first to fourth types of layered type liquid crystal elements according to the following embodiments may have, e.g., a plurality of the corresponding type of liquid crystal elements layered together.

In the layered type liquid crystal element wherein a plurality of liquid crystal elements (liquid crystal cells) are overlaid on each other, two substrates are arranged between adjacent two liquid crystal layers since each of the liquid crystal layer is held between a pair of substrates. In contrast to above layered type liquid crystal element, only one substrate may be arranged between adjacent two liquid crystal layers in any type of layered type liquid crystal elements according to the following embodiments, and the substrate arranged between adjacent two liquid crystal layers may be commonly used for holding those liquid crystal layers. In other words, as described above, the substrate used for holding one liquid crystal layer among a plurality of liquid crystal layers may be used for holding the other liquid crystal layer.

Any type of the first to fourth types of layered type liquid crystal elements according to the following embodiments may have three liquid crystal layers, i.e., a liquid crystal layer for red display (e.g., a liquid crystal layer having a selective reflection wavelength in the red region), a liquid crystal layer for green display (e.g., a liquid crystal layer having a selective reflection wavelength in the green region) and a liquid crystal layer for blue display (e.g., a liquid crystal layer having a selective reflection wavelength in the blue region), for performing multicolor display.

### [1-5] ORGANIC ELECTRO-LUMINESCENCE ELEMENT (ORGANIC EL ELEMENT)

In the following embodiments, four types of organic EL elements (first to fourth types of organic EL elements) are presented.

Any type of organic EL elements (single layered organic EL elements) according to the following embodiments has an organic luminescent film. The organic luminescent film may be formed of a single layer, i.e., an organic luminescent layer, or two or more layered layers at least including the organic luminescent layer.

In any type of organic EL elements according to the following embodiments, the organic luminescent film is held between a pair of substrates or is carried on one substrate. Any type of organic EL elements according to the following embodiments has one or more substrates for holding the organic luminescent film therebetween or carrying the same thereon.

In any type of organic EL elements according to the following embodiments, a resin substrate is employed as the substrate for holding or carrying the organic luminescent film. In any type of organic EL elements according to the following embodiments, when a plurality of substrates are used, at least one of them may be the resin substrate.

In any type of organic EL elements according to the following embodiments, a plurality of layers including an electrode are formed on the resin substrate for holding or carrying the organic luminescent film.

In any type of organic EL elements according to the following embodiments, features reside in the layer(s) formed on the resin substrate for holding or carrying the organic luminescent film, the layer structure and others. The first to fourth types of organic EL elements according to the following embodiments differ from each other in the layers formed on the resin substrate and in the layer structure.

The layers formed on the resin substrate in the first to fourth types of organic EL elements according to the following embodiments and the layer structure are the same as those in the first to fourth types of single layered display elements of the following embodiments.

### [1-6] LAYERED TYPE ORGANIC EL ELEMENT (OVERLAY TYPE ORGANIC EL ELEMENT)

In the following embodiments, four types of layered type organic EL elements (first to fourth types of layered type organic EL elements) in each of which a plurality of organic luminescent films are layered together are also presented.

In any type of layered type organic EL elements (overlay type organic EL elements) according to the following embodiments, each organic luminescent film is held between a pair of substrates or is carried on a substrate, similar to the single layered organic EL elements of the following embodiments. In any type of layered type organic EL elements (overlay type organic EL elements) according to the following embodiments, each of one or more among plural organic luminescent films may be held between a pair of substrates, and each of one or more remaining organic luminescent film(s) may be carried on one substrate. In any type of layered type organic EL elements (overlay type organic EL elements) according to the following embodiments, the substrates used for holding or carrying one organic luminescent film among a plurality of organic luminescent films may be utilized for holding or carrying the other organic luminescent film.

In any type of layered type organic EL elements (overlay type organic EL elements) according to the following embodiments, a plurality of substrates are provided for holding or carrying a plurality of electro-luminescent films. In any type of layered type organic EL elements (overlay type organic EL elements) according to the following embodiments, a resin substrate is employed as the substrate for holding or carrying the organic luminescent film. In any type of layered type organic EL elements (overlay type organic EL elements) according to the following embodiments, at least one of the plural substrates may be the resin substrate.

In any type of layered type organic EL elements (overlay type organic EL elements) according to the following embodiments, a plurality of layers including an electrode are formed on the resin substrate for holding or carrying the organic luminescent film, similar to the single layered organic EL elements of the following embodiments.

In any type of layered type organic EL elements (overlay type organic EL elements) according to the following embodiments, features reside in the layer(s) formed on the resin substrate for holding or carrying the organic luminescent film, in the layer structure and others. The first to fourth types of layered type organic EL elements (overlay type organic EL elements) according to the following embodiments differ from each other in the layers formed on the resin substrate and in the layer structure.

The layers formed on the resin substrate and the layer structure in the first to fourth types of layered type organic EL elements (overlay type organic EL elements) according to the following embodiments are the same as those in the first to fourth types of display elements according to the following embodiments, respectively.

Any of the first to fourth types of layered type organic El elements (overlay type organic EL elements) according to the following embodiments may have, e.g., three layered organic luminescent films, i.e., an organic luminescent film for red luminescence, an organic luminescent film for green luminescence, and an organic luminescent film for blue luminescence, for performing multicolor display.

[2] Description will be given below, on a type by type basis, on the first to fourth type of the display elements, liquid crystal elements, organic EL elements, layered type display elements, layered type liquid crystal elements and layered type organic EL elements(overlay type organic EL elements).

### [2-1] FIRST TYPE

[2-1-1] Described below are the first type display element, layered type display element, liquid crystal element, layered type liquid crystal element, organic EL element, and layered type organic EL element (overlay type organic EL element).

The first type display element is a display element comprising: a display layer; and a member which holds or carries the display layer, the member comprising: a resin substrate; an anchor layer formed on the resin substrate; a gas barrier layer formed on the anchor layer, the gas barrier layer being made of SiOₓ (0<x≦2) or Al₂O₃; and a transparent electrode formed on the gas barrier layer, the transparent electrode being made of an amorphous oxide comprising indium (In), zinc (Zn) and oxygen (O) as essential constituent elements.

The first type of layered type display element is a layered type display element comprising: a plurality of display layers layered together; and a member which holds or carries at least one of the display layers, the member comprising: a resin substrate; an anchor layer formed on the resin substrate; a gas barrier layer formed on the anchor layer, the gas barrier layer being made of SiOₓ (0<x≦2) or Al₂O₃; and a transparent electrode formed on the gas barrier layer, the transparent electrode being made of an amorphous oxide comprising indium (In), zinc (Zn) and oxygen (O) as essential constituent elements.

The first type liquid crystal element is a liquid crystal element comprising: a liquid crystal layer; and a member which holds the liquid crystal layer, the member comprising: a resin substrate; an anchor layer formed on the resin substrate; a gas barrier layer formed on the anchor layer, the gas barrier layer being made of SiOₓ (0<x≦2) or Al₂O₃; and a transparent electrode formed on the gas barrier layer, the transparent electrode being made of an amorphous oxide comprising indium (In), zinc (Zn) and oxygen (O) as essential constituent elements.

The first type of layered type liquid crystal element is a layered type liquid crystal element comprising: a plurality of liquid crystal layers layered together; and a member which holds at least one of the liquid crystal layers, the member comprising: a resin substrate; an anchor layer formed on the resin substrate; a gas barrier layer formed on the anchor layer, the gas barrier layer being made of SiOₓ (0<x≦2) or Al₂O₃; and a transparent electrode formed on the gas barrier layer, the transparent electrode being made of an amorphous oxide comprising indium (In), zinc (Zn) and oxygen (O) as essential constituent elements.

The first type organic electro-luminescence element (organic EL element) is an organic electro-luminescence element comprising: an organic electro-luminescent film; and a member which holds or carries the organic electro-luminescent film, the member comprising: a resin substrate; an anchor layer formed on the resin substrate; a gas barrier layer formed on the anchor layer, the gas barrier layer being made of SiOₓ (0<x≦2) or Al₂O₃; and a transparent electrode formed on the gas barrier layer, the transparent electrode being made of an amorphous oxide comprising indium (In), zinc (Zn) and oxygen (O) as essential constituent elements.

The first type of layered type organic electro-luminescence element (overlay type organic EL element) is a layered type organic electro-luminescence element comprising: a plurality of organic electro-luminescent films layered together; and a member which holds or carries at least one of the organic electro-luminescent films, the member comprising: a resin substrate; an anchor layer formed on the resin substrate; a gas barrier layer formed on the anchor layer, the gas barrier layer being made of SiOₓ (0<x≦2) or Al₂O₃; and a transparent electrode formed on the gas barrier layer, the transparent electrode being made of an amorphous oxide comprising indium (In), zinc (Zn) and oxygen (O) as essential constituent elements.

[2-1-2] In any of these first type elements (first type display element, liquid crystal element, organic electro-luminescence element, layered type display element, layered type liquid crystal element and layered type organic electro-luminescence element), the gas barrier layer and the transparent electrode are formed on one surface of the resin substrate in this order from the substrate side, and the anchor layer is formed between the resin substrate and the gas barrier layer. That is, in the first type element, the anchor layer, gas barrier layer and transparent electrode are formed on one surface of the resin substrate in this order from the substrate side.

The gas barrier layer is provided for preventing the entry of water, oxygen (O₂) and others into the display layer, liquid crystal layer, organic luminescent film or others. The gas barrier layer is formed of SiOₓ (silica) or Al₂O₃ (alumina).

The anchor layer is provided for increasing the adhesion of the gas barrier layer to the substrate. Consequently the anchor layer is preferably arranged in such a position that the anchor layer is in direct contact with the gas barrier layer.

The electrode is made of an amorphous oxide comprising indium (In), zinc (Zn) and oxygen (O) as essential constituent elements. Hereinafter, the material termed “amorphous oxide comprising indium (In), zinc (Zn) and oxygen (O) as essential constituent elements” may be referred to simply as “IZO”.

A problem of cracks or the like occurring in the electrode is unlikely to arise during the production of the first type element because the electrode is made of IZO which is not crystallized in a high-temperature environment and which is highly rigid. IZO is more unlikely to cause damages such as a crack than ITO frequently used as the material for the electrode, so that the first type element can be produced in a higher yield. The electrode having a relatively low resistance can be produced from IZO, which can lower a drive voltage. IZO can exhibit a light transmittance of 80% or more, and therefore does not impair the transparency of the whole element when IZO is used as the material for the electrode.

Since the gas barrier layer is formed on the resin substrate in the first type element, the deterioration of the display layer, liquid crystal layer, organic luminescent film or others can be suppressed, even when the element is used in a high temperature/high humidity environment. Therefore, the first type element can stably provide good display or good luminescence for a long term.

In the first type element, the anchor layer is formed between the resin substrate and the gas barrier layer made of inorganic material, whereby the adhesion of the gas barrier layer to the substrate can be enhanced. The anchor layer can suppress the release or peel of the gas barrier layer from the substrate. Thereby the gas barrier layer can achieve its contemplated object for a long time period.

Optionally the first type element may have an undercoat layer arranged between the electrode and the resin substrate for increasing the adhesion of the electrode to the substrate. Preferably the undercoat layer may be arranged in such a position that the undercoat layer is in direct contact with the electrode. The undercoat layer thus provided for the electrode can increase the adhesion of the electrode to the substrate, similar to the anchor layer provided for the gas barrier layer. Thereby the electrode can achieve the contemplated object for a long term.

### [2-2] SECOND TYPE

[2-2-1] Described below are the second type display element, layered type display element, liquid crystal element, layered type liquid crystal element, organic EL element and layered type organic EL element (overlay type organic EL element).

The second type display element is a display element comprising: a display layer; and a member which holds or carries the display layer, the member comprising: a resin substrate having a first surface and a second surface opposing the first surface; a gas barrier layer formed on the first surface of the resin substrate, the gas barrier layer being made of SiOₓ (0<x≦2) or Al₂O₃; and a transparent electrode formed on the second surface of the resin substrate, the transparent electrode being made of an amorphous oxide comprising indium (In), zinc (Zn) and oxygen (O) as essential constituent elements.

The second type of layered type display element is a layered type display element comprising: a plurality of display layers layered together; and a member which holds or carries at least one of the display layers, the member comprising: a resin substrate having a first surface and a second surface opposing the first surface; a gas barrier layer formed on the first surface of the resin substrate, the gas barrier layer being made of SiOₓ (0<x≦2) or Al₂O₃; and a transparent electrode formed on the second surface of the resin substrate, the transparent electrode being made of an amorphous oxide comprising indium (In), zinc (Zn) and oxygen (O) as essential constituent elements.

The second type liquid crystal element is a liquid crystal element comprising: a liquid crystal layer; and a member which holds the liquid crystal layer, the member comprising: a resin substrate having a first surface and a second surface opposing the first surface; a gas barrier layer formed on the first surface of the resin substrate, the gas barrier layer being made of SiOₓ (0<x≦2) or Al₂O₃; and a transparent electrode formed on the second surface of the resin substrate, the transparent electrode being made of an amorphous oxide comprising indium (In), zinc (Zn) and oxygen (O) as essential constituent elements.

The second type of layered type liquid crystal element is a layered type liquid crystal element comprising: a plurality of liquid crystal layers layered together; and a member which holds at least one of the liquid crystal layers, the member comprising: a resin substrate having a first surface and a second surface opposing the first surface; a gas barrier layer formed on the first surface of the resin substrate, the gas barrier layer being made of SiOₓ (0<x≦2) or Al₂O₃; and a transparent electrode formed on the second surface of the resin substrate, the transparent electrode being made of an amorphous oxide comprising indium (In), zinc (Zn) and oxygen (O) as essential constituent elements.

The second type organic electro-luminescence element (organic EL element) is an organic electro-luminescence element comprising: an organic electro-luminescent film; and a member which holds or carries the organic electro-luminescent film, the member comprising: a resin substrate having a first surface and a second surface opposing the first surface; a gas barrier layer formed on the first surface of the resin substrate, the gas barrier layer being made of SiOₓ (0<x≦2) or Al₂O₃; and a transparent electrode formed on the second surface of the resin substrate, the transparent electrode being made of an amorphous oxide comprising indium (In), zinc (Zn) and oxygen (O) as essential constituent elements.

The second type of layered type organic electro-luminescence element (overlay type organic EL element) is a layered type organic electro-luminescence element comprising: a plurality of organic electro-luminescent films layered together; and a member which holds or carries at least one of the organic electro-luminescent films, the member comprising: a resin substrate having a first surface and a second surface opposing the first surface; a gas barrier layer formed on the first surface of the resin substrate, the gas barrier layer being made of SiOₓ (0<x≦2) or Al₂O₃; and a transparent electrode formed on the second surface of the resin substrate, the transparent electrode being made of an amorphous oxide comprising indium (In), zinc (Zn) and oxygen (O) as essential constituent elements.

[2-2-2] In any of these second type elements (second type display element, liquid crystal element, organic EL element, layered type display element, layered type liquid crystal element and layered type organic EL element), the gas barrier layer is formed on one surface of the resin substrate, and the transparent electrode is formed on the other surface of the resin substrate.

In the second type element, the gas barrier layer is made of SiOₓ (0<x≦2) or Al₂O₃ as in the first type element. The electrode is made of IZO, i.e., an amorphous oxide comprising indium (In), zinc (Zn) and oxygen (O) as essential constituent elements.

A problem of cracks or the like occurring in the electrode is unlikely to arise during the production of the second type element, as in the first type element, because IZO is used as the material for electrode, so that the second type element can be produced in a higher yield.

Since the gas barrier layer is formed on the resin substrate in the second type element, the deterioration of the display layer, liquid crystal layer, organic luminescent film or others can be suppressed even when the second type element is used in a high temperature/high humidity environment. Therefore, the second type element can stably perform good display or good luminescence for a long term.

In the second type element, an anchor layer may be arranged between the resin substrate and the gas barrier layer in order to increase the adhesion of the gas barrier layer to the substrate. According to this, the same effect as in the first type element can be achieved.

Optionally the second type element may have an undercoat layer arranged between the electrode and the resin substrate, as described above concerning the first type element, for increasing the adhesion of the electrode to the resin substrate. According to this, the same effect as in the first type element can be achieved.

### [2-3] THIRD TYPE

[2-3-1] Described below are the third type display element, layered type display element, liquid crystal element, layered type liquid crystal element, organic EL element, and layered type organic EL element (overlay type organic EL element).

The third type display element is a display element comprising: a display layer; and a member which holds or carries the display layer, the member comprising: a resin substrate having a first surface and a second surface opposing the first surface; a gas barrier layer formed on the first surface of the resin substrate, the gas barrier layer being made of SiOₓ (0<x≦2) or Al₂O₃; a transparent electrode formed on the gas barrier layer, the transparent electrode being made of an amorphous oxide comprising indium (In), zinc (Zn) and oxygen (O) as essential constituent elements; and a hard coat layer formed on the second surface of the resin substrate.

The third type of layered type display element is a layered type display element comprising: a plurality of display layers layered together; and a member which holds or carries at least one of the display layers, the member comprising: a resin substrate having a first surface and a second surface opposing the first surface; a gas barrier layer formed on the first surface of the resin substrate, the gas barrier layer being made of SiOₓ (0<x≦2) or Al₂O₃; a transparent electrode formed on the gas barrier layer, the transparent electrode being made of an amorphous oxide comprising indium (In), zinc (Zn) and oxygen (O) as essential constituent elements; and a hard coat layer formed on the second surface of the resin substrate.

The third type liquid crystal element is a liquid crystal element comprising: a liquid crystal layer; and a member which holds the liquid crystal layer, the member comprising: a resin substrate having a first surface and a second surface opposing the first surface; a gas barrier layer formed on the first surface of the resin substrate, the gas barrier layer being made of SiOₓ (0<x≦2) or Al₂O₃; a transparent electrode formed on the gas barrier layer, the transparent electrode being made of an amorphous oxide comprising indium (In), zinc (Zn) and oxygen (O) as essential constituent elements; and a hard coat layer formed on the second surface of the resin substrate.

The third type of layered type liquid crystal element is a layered type liquid crystal element comprising: a plurality of liquid crystal layers layered together; and a member which holds at least one of the liquid crystal layers, the member comprising: a resin substrate having a first surface and a second surface opposing the first surface; a gas barrier layer formed on the first surface of the resin substrate, the gas barrier layer being made of SiOₓ (0<x≦2) or Al₂O₃; a transparent electrode formed on the gas barrier layer, the transparent electrode being made of an amorphous oxide comprising indium (In), zinc (Zn) and oxygen (O) as essential constituent elements; and a hard coat layer formed on the second surface of the resin substrate.

The third type organic electro-luminescence element (organic EL element) is an organic electro-luminescence element comprising: an organic electro-luminescent film; and a member which holds or carries the organic electro-luminescent film, the member comprising: a resin substrate having a first surface and a second surface opposing the first surface; a gas barrier layer formed on the first surface of the resin substrate, the gas barrier layer being made of SiOₓ (0<x≦2) or Al₂O₃; a transparent electrode formed on the gas barrier layer, the transparent electrode being made of an amorphous oxide comprising indium (In), zinc (Zn) and oxygen (O) as essential constituent elements; and a hard coat layer formed on the second surface of the resin substrate.

The third type of layered type organic electro-luminescence element (overlay type organic EL element) is a layered type organic electro-luminescence element comprising: a plurality of organic electro-luminescent films layered together; and a member which holds or carries at least one of the organic electro-luminescent films, the member comprising: a resin substrate having a first surface and a second surface opposing the first surface; a gas barrier layer formed on the first surface of the resin substrate, the gas barrier layer being made of SiOₓ (0<x≦2) or Al₂O₃; a transparent electrode formed on the gas barrier layer, the transparent electrode being made of an amorphous oxide comprising indium (In), zinc (Zn) and oxygen (O) as essential constituent elements; and a hard coat layer formed on the second surface of the resin substrate.

[2-3-2] In any of these third type elements (third type display element, liquid crystal element, organic EL element, layered type display element, layered type liquid crystal element and layered type organic EL element), the gas barrier layer and the transparent electrode are formed on one surface of the resin substrate in this order from the substrate side, and the hard coat layer is formed on the other surface of the resin substrate.

In the third type element, the gas barrier layer is made of SiOₓ (0<x≦2) or Al₂O₃, and the electrode is made of IZO, i.e., an amorphous oxide comprising indium (In), zinc (Zn) and oxygen (O) as essential constituent elements, as in the first type element.

The hard coat layer is provided for preventing marring or the like of the resin substrate.

A problem of cracks or the like occurring in the electrode is unlikely to arise during the production of third type element because IZO is used as the material for electrode, as in the first type element, so that the third type element can be produced in a higher yield.

The gas barrier layer is formed on the resin substrate in the third type element, whereby the deterioration of the display layer, liquid crystal layer, organic luminescent film or others can be suppressed, even when the third type element is used in a high temperature/high humidity environment. Therefore, the third type element can stably provide good display or good luminescence for a long term.

In the third type element, the hard coat layer is formed on the resin substrate so that the marring of the substrate can be suppressed during the production of the element and during the use thereof, whereby the deterioration of the display quality or luminous quality can be suppressed. The hard coat layer may be preferably arranged on the outermost side of the third type element.

In the third type element, an anchor layer may be arranged between the substrate and the gas barrier layer, as in the first type element, for increasing the adhesion of the gas barrier layer to the substrate. By doing this, the same effect as in the first type element can be achieved.

In the third type element, an undercoat layer may be formed between the electrode and the substrate, as described concerning the first type element, for increasing the adhesion of the electrode to the resin substrate. By doing this, the same effect as in the first type element can be achieved.

### [2-4] FOURTH TYPE

[2-4-1] Described below are the fourth type display element, layered type display element, liquid crystal element, layered type liquid crystal element, organic EL element and layered type organic EL element (overlay type organic EL element).

The fourth type display element is a display element comprising: a display layer; and a member which holds or carries the display layer, the member comprising: a resin substrate having a first surface and a second surface opposing the first surface; a gas barrier layer formed on the first surface of the resin substrate, the gas barrier layer being made of SiOₓ (0<x≦2) or Al₂O₃; a hard coat layer formed on the gas barrier layer; and a transparent electrode formed on the second surface of the resin substrate, the transparent electrode being made of an amorphous oxide comprising indium (In), zinc (Zn) and oxygen (O) as essential constituent elements.

The fourth type of layered type display element is a layered type display element comprising: a plurality of display layers layered together; and a member which holds or carries at least one of the display layers, the member comprising: a resin substrate having a first surface and a second surface opposing the first surface; a gas barrier layer formed on the first surface of the resin substrate, the gas barrier layer being made of SiOₓ (0<x≦2) or Al₂O₃; a hard coat layer formed on the gas barrier layer; and a transparent electrode formed on the second surface of the resin substrate, the transparent electrode being made of an amorphous oxide comprising indium (In), zinc (Zn) and oxygen (O) as essential constituent elements.

The fourth type liquid crystal element is a liquid crystal element comprising: a liquid crystal layer; and a member which holds the liquid crystal layer, the member comprising: a resin substrate having a first surface and a second surface opposing the first surface; a gas barrier layer formed on the first surface of the resin substrate, the gas barrier layer being made of SiOₓ (0<x≦2) or Al₂O₃; a hard coat layer formed on the gas barrier layer; and a transparent electrode formed on the second surface of the resin substrate, the transparent electrode being made of an amorphous oxide comprising indium (In), zinc (Zn) and oxygen (O) as essential constituent elements.

The fourth type of layered type liquid crystal element is a layered type liquid crystal element comprising: a plurality of liquid crystal layers layered together; and a member which holds at least one of the liquid crystal layers, the member comprising: a resin substrate having a first surface and a second surface opposing the first surface; a gas barrier layer formed on the first surface of the resin substrate, the gas barrier layer being made of SiOₓ (0<x≦2) or Al₂O₃; a hard coat layer formed on the gas barrier layer; and a transparent electrode formed on the second surface of the resin substrate, the transparent electrode being made of an amorphous oxide comprising indium (In), zinc (Zn) and oxygen (O) as essential constituent elements.

The fourth type organic electro-luminescence element (organic EL element) is an organic electro-luminescence element comprising: an organic electro-luminescent film; and a member which holds or carries the organic electro-luminescent film, the member comprising: a resin substrate having a first surface and a second surface opposing the first surface; a gas barrier layer formed on the first surface of the resin substrate, the gas barrier layer being made of SiOₓ (0<x≦2) or Al₂O₃; a hard coat layer formed on the gas barrier layer; and a transparent electrode formed on the second surface of the resin substrate, the transparent electrode being made of an amorphous oxide comprising indium (In), zinc (Zn) and oxygen (O) as essential constituent elements.

The fourth type of layered type organic electro-luminescence element (overlay type organic EL element) is a layered type organic electro-luminescence element comprising: a plurality of organic electro-luminescent films layered together; and a member which holds or carries at least one of the organic electro-luminescent films, the member comprising: a resin substrate having a first surface and a second surface opposing the first surface; a gas barrier layer formed on the first surface of the resin substrate, the gas barrier layer being made of SiOₓ (0<x≦2) or Al₂O₃; a hard coat layer formed on the gas barrier layer; and a transparent electrode formed on the second surface of the resin substrate, the transparent electrode being made of an amorphous oxide comprising indium (In), zinc (Zn) and oxygen (O) as essential constituent elements.

[2-4-2] In any of these fourth type elements (fourth type display element, liquid crystal element, organic EL element, layered type display element, layered type liquid crystal element and layered type organic EL element), the gas barrier layer and the hard coat layer are formed on one surface of the resin substrate in this order from the substrate side, and the transparent electrode is formed on the other surface of the resin substrate.

In the fourth type element, the gas barrier layer is made of SiOₓ (0<x≦2) or Al₂O₃, as in the first type element. The transparent electrode is made of IZO, i.e., an amorphous oxide comprising indium (In), zinc (Zn) and oxygen (O) as essential constituent elements. The hard coat layer is provided for preventing the marring of the resin substrate.

In the fourth type element, a problem of cracks or the like occurring in the electrode is unlikely to arise during the production of the element because IZO is used as the material for electrode, as in the first type element, so that the fourth type element can be produced in a higher yield.

In the fourth type element, the gas barrier layer is formed on the resin substrate, whereby the deterioration of the display layer, liquid crystal layer, organic luminescent film or others can be suppressed even when the fourth type element is used in a high temperature/high humidity environment. Therefore, the fourth type element can stably provide good display or good luminescence for a long term.

In the fourth type element, the hard coat layer is formed on the resin substrate, as in the third type element, thereby the marring of the resin substrate during the production of the element and during the use thereof can be suppressed, whereby the deterioration of the display quality or luminous quality can be suppressed. The hard coat layer may be preferably provided on the outermost side of the fourth type element.

In the fourth type element, an anchor layer may be arranged between the resin substrate and the gas barrier layer, as in the first type element, for increasing the adhesion of the gas barrier layer to the resin substrate. According to this, the same effect as in the first type element can be achieved.

Optionally in the fourth type element, an undercoat layer may be arranged between the electrode and the substrate, as described above concerning the first type element, for increasing the adhesion of the electrode to the substrate. By doing this, the same effect as in the first type element can be achieved.

[3] The following may be employed in any of the foregoing first to fourth types of elements.

The resin substrate may be made of, for example, polyether sulfone (PES), polycarbonate (PC), polyethylene terephthalate (PET), polyarylate (PA), polyether ether ketone (PEEK) or others. The resin substrate may be, e.g. a film or sheet substrate, and may have a thickness in a range, e.g. from about 50 μm to about 1000 μm. If the thin resin substrate is used, the element can be reduced in the thickness and the weight. Even if the thin resin substrate is used, the penetration of water and oxygen can be hindered by the gas barrier layer formed on the resin substrate as described above.

The electrode is made of IZO, i.e., the amorphous oxide comprising indium (In), zinc (Zn) and oxygen (O) as essential constituent elements as described above. The amorphous oxide may further contain at least one species of halogen selected from fluorine (F), chlorine (Cl), bromine (Br), iodine (I) and astatine (At). The resistance value and the heat stability of the electrode can be improved by further incorporating at least one species of halogen into the amorphous oxide. Especially the incorporation of chlorine would be likely to give good characteristics and is advantageous in terms of costs. The IZO electrode may be formed typically by a sputtering method and can be made by an ion plating method, a coating thermal decomposition method, a vacuum deposition method, a CVD method or others. The IZO electrode may have a thickness in a range from about 20 nm to about 300 nm.

The gas barrier layer is made of SiOₓ or Al₂O₃ as mentioned above and may be formed, e.g. by a sputtering method. The thickness of the gas barrier layer may be in a range, e.g., from about 1 nm to about 200 nm.

The anchor layer arranged between the gas barrier layer and the resin substrate may be made of, e.g. a urethane resin or acrylic resin. The thickness of the anchor layer may be in a range, e.g., from about 1 μm to about 3 μm. The anchor layer may be formed, e.g. by an application method.

The undercoat layer arranged between the electrode and the resin substrate may be made of, e.g. a urethane resin and may have a thickness in a range, e.g., from about 1 μm to about 3 μm. The undercoat layer can be formed by, e.g. an application method.

The hard coat layer may be made of, e.g. a thermosetting epoxy-containing resin or UV-curing acrylic-containing resin, and may have a thickness, e.g., from about 0.5 μm to about 5 μm. The hard coat layer may be formed by, e.g. an application method.

[4-1] In any of the first to fourth types of liquid crystal elements, at least one (first substrate) of the paired substrates (first and second substrates) for holding the liquid crystal layer therebetween is the resin substrate. If each of the first and second substrates is the resin substrates, the thickness and weight of the liquid crystal element can be reduced accordingly. The other substrate (second substrate) may be, e.g. a glass substrate. The gas barrier layer, electrode and others may be formed, as mentioned above, on at least one resin substrate (first substrate) according to the type of the element. When the other substrate (second substrate) is also the resin substrate, it is desirable to form the gas barrier layer on the second substrate for preventing the deterioration of the liquid crystal layer and others due to water and oxygen. If a pair of substrates (first and second substrates) for holding the liquid crystal layer therebetween are both resin substrates, the layer(s) formed on the first substrate and the layer structure thereof may differ from the layer(s) on the second substrate and the layer structure thereof. For example, the first substrate may have the layers to be formed in the first type liquid crystal element, and the second substrate may have the layers to be formed in the second type liquid crystal element.

The same is true when any type of the first to fourth types of display elements or organic EL elements has a pair of substrates for holding the display layer or organic luminescent film therebetween. When any type of the first to fourth types of display elements or organic EL elements has only a single substrate for carrying the display layer or organic luminescent film thereon, it is desirable to protect the display layer, organic luminescent film or others against water and oxygen using a seal member, a seal resin and/or others.

[4-2] In any of the first to fourth types of layered type liquid crystal elements, at least one of the plural substrates for holding the liquid crystal layers is the resin substrate. If all of the substrates are the resin substrates, the thickness and the weight of the element can be reduced accordingly. The gas barrier layer, electrode and other layer as described above are formed on at least one resin substrate according to the type of the element as described above. When the other substrate(s) are the resin substrates, it is desirable to form the gas barrier layer on the resin substrate for preventing the deterioration of the liquid crystal layer due to water and oxygen. In any of the first to fourth types of layered type liquid crystal elements, when a plurality of substrates are the resin substrates, the layer(s) formed on one or more resin substrate(s) and the layer structure thereof may differ from the layer(s) on the other resin substrate(s) and the layer structure thereof.

The same is true in any of the first to fourth types of layered type display elements or layered type organic EL elements (overlay type organic EL elements). In any of the first to fourth types of display elements or organic EL elements, the display layer, organic luminescent film or others may be protected against water and oxygen using a seal member, a seal resin and/or others.

[5] In any of the first to fourth types of liquid crystal elements and in any of the first to fourth types of layered type liquid crystal elements, the liquid crystal layer may be, for example, as described below.

The liquid crystal layer includes the liquid crystal as stated above.

The liquid crystal layer may further include spacer(s) for adjusting the thickness of the liquid crystal (liquid crystal layer) and may further include resin structures) for adhering together the two substrates for holding the liquid crystal layer therebetween or for increasing the strength of the liquid crystal element in its entirety. The liquid crystal layer may be the so-called liquid crystal composite film of polymer-dispersed type. The liquid crystal composite film of polymer-dispersed type may be, for example, a film wherein the liquid crystal is dispersed in a three-dimensional network structure of polymers, or a film wherein the three-dimensional network structure of polymers is formed in the liquid crystal.

The liquid crystal (liquid crystal composition) in the liquid crystal layer may be a liquid crystal composition containing a liquid crystal exhibiting a cholesteric phase (e.g., a liquid crystal exhibiting a cholesteric phase at room temperature). The liquid crystal composition in the liquid crystal layer may contain a dye or dyes. The liquid crystal exhibiting the cholesteric phase selectively reflects the light of the wavelength depending on the helical pitch of liquid crystal. Therefore, the liquid crystal element containing the liquid crystal exhibiting the cholesteric phase can be used as a liquid crystal display element of a reflection type. Similarly the layered type liquid crystal element having a plurality of liquid crystal layers, each containing the liquid crystal exhibiting the cholesteric phase, can be utilized as the liquid crystal display element of the reflection type.

The liquid crystal exhibiting the cholesteric phase may be a cholesteric liquid crystal which exhibits the cholesteric phase by itself, or a chiral nematic liquid crystal composition including a nematic liquid crystal composition and a chiral material (chiral agent) added thereto. The chiral nematic liquid crystal composition has the advantages that the helical pitch can be adjusted by controlling an amount of the added chiral material, and thereby the selective reflection wavelength can be easily adjusted. The helical pitch is a pitch of a spiral structure of the liquid crystal molecules, and is a distance between the liquid crystal molecules twisted by 360 degrees from each other along the spiral structure of the liquid crystal molecules. The selective reflection wavelength may be set in a visible light range or an invisible light range (e.g., infrared ray range).

The nematic liquid crystal composition has rod-like liquid crystal molecules which are parallel to each other, but does not have a layered structure. The nematic liquid crystal composition for the chiral nematic liquid crystal composition is not restricted to a specific nematic composition, and various kinds of nematic compositions can be used as the nematic liquid crystal composition for the chiral nematic liquid crystal composition. In particular, the nematic liquid crystal composition containing the liquid crystal compound having a polar group such as a liquid crystal ester compound, liquid crystal pyrimidine compound, liquid crystal cyanobiphenyl compound, liquid crystal cyanophenylcyclohexane compound, liquid crystal cynanoterphenyl compound, liquid crystal difluorostilbene compound or liquid crystal tolane compound, is useful because it can increase the dielectric anisotropy of the chiral nematic liquid crystal composition. The nematic liquid crystal composition may be a mixture of two or more kinds of liquid crystal compound. The nematic liquid crystal composition may contain liquid crystal compounds other than the above, and more specifically may contain a polycyclic compound or an N-type compound for increasing a temperature of phase transition to an isotropic phase.

The chiral material is an additive having a function of twisting the molecules of nematic liquid crystal composition. By adding the chiral material to the nematic liquid crystal composition, the liquid crystal molecules can have the spiral structure which has a twist distance depending on the amount of added chiral material. As a result, the liquid crystal composition containing the nematic liquid crystal composition and the chiral material added thereto can exhibit the cholesteric phase.

The chiral material may contain at least one kind of compound having at least one asymmetry carbon, and the helical senses (twist directions of the liquid crystal composition) thereof may be uniform or different. The addition rate of the chiral material is preferably about 45% or less by weight with respect to the nematic liquid crystal composition, and 40% or less by weight is more preferable. If the addition rate exceeds 45% by weight, the disadvantages such as precipitation of crystal is liable to occur. The lower limit of the addition rate of chiral material is not particularly restricted if an intended effect can be achieved, but 10% or more by weight is preferable.

Two or more kinds of chiral materials may be added to the nematic liquid crystal composition. Two or more kinds of chiral materials having the same optical rotation, alternatively, two or more kinds of chiral materials having different optical rotations may be added to the nematic liquid crystal composition. By adding two or more kinds of chiral materials to the nematic liquid crystal composition and/or by adding the liquid crystal components such as a polycyclic compound and an N-type compound, it is possible to change the phase transition temperature of the chiral nematic liquid crystal composition and suppress the change in selective reflection wavelength due to change in temperature. Also, it is possible to change the properties of the chiral nematic liquid crystal composition such as a dielectric anisotropy, refractive index anisotropy and viscosity. Thereby, properties of the liquid crystal display element can be improved.

In the liquid crystal element and the layered type liquid crystal element, a dye(s) may be added to the element component, and/or a colored filter layer (filter layer) such as a color glass filter or color film may be provided, for improving the purity of color displayed when the incident light is selectively reflected, and/or for absorbing the light components which may lower the transparency of the liquid crystal composition in the transparent state. The dye(s) may be added to the liquid crystal composition, resin material, electrode material and/or substrate material. For preventing the lowering of the display quality, it is preferable that the dye(s) and the colored filter layer do not impede the color display performed by the selective reflection.

[6] The organic luminescent film may be, e.g. as described below in any of first to fourth types of organic electro-luminescence elements and any of first to fourth types of layered type organic electro-luminescence elements (overlay type organic electro-luminescence elements).

[6-1] The organic luminescent film contains at least an organic luminescent layer. As described later, the organic luminescent film may have a single structure consisting of the organic luminescent layer alone or a layered structure consisting of a plurality of layers including the organic luminescent layer. The organic luminescent film may contain a plurality of organic luminescent layers layered together.

The organic luminescent film may be selected from:

(a1) a hole transport-related layer and an organic luminescent layer layered in this order from the positive electrode side to the negative electrode side,

(a2) a hole transport-related layer, an organic luminescent layer and an electron transport-related layer layered in this order from the positive electrode side to the negative electrode side, and

(a3) an organic luminescent layer and an electron transport-related layer layered in this order from the positive electrode side to the negative electrode side.

In the organic electro-luminescence element, light is given off as follows. When electron is injected from one (negative electrode) of the electrodes and a hole is injected from the other electrode (positive electrode), the electron is combined with the hole in the organic luminescent layer, whereby the organic luminescent material forming the organic luminescent layer is energized toward a higher level of energy, and the superfluous energy is emitted as light when the energized organic luminescent material returns to the original normal state.

Thus, the luminous efficiency can be increased by the provision of the hole transport-related layer and/or the electron transport-related layer in the organic luminescent film for enhancing the transport efficiency of an electric charge (hole or electron). The provision of the hole transport-related layer and/or the electron transport-related layer can increase the injection efficiency of the electric charge from the electrode to the organic luminescent film and thus can increase the luminous efficiency.

The hole transport-related layer may be one selected from the group consisting of:

(b1) a hole injection layer,

(b2) a hole transport layer,

(b3) a hole injection layer and a hole transport layer, and

(b4) a hole injection/transport layer.

The hole transport-related layer may be properly selected in accordance with the characteristics of the electrode and the characteristics of the organic luminescent layer. Since none of the hole transport layer and the hole injection/transport layer transport any electron, the electron can be confined to the organic luminescent layer by the provision of either of them, resulting in increase of luminous efficiency.

The electron transport-related layer may be selected from the group consisting of:

(c1) an electron injection layer,

(c2) an electron transport layer,

(c3) an electron injection layer and an electron transport layer, and

(c4) an electron injection/transport layer.

The electron transport-related layer may be appropriately selected in accordance with the characteristics of the electrode and the characteristics of the organic luminescent layer. Since none of the electron transport layer and the electron injection/transport layer transport any hole, the hole can be confined to the organic luminescent layer by the provision of either of them, resulting in increase of luminous efficiency.

The hole transport-related layer, organic luminescent layer and electron transport-related layer will be described below in this order in more detail.

### [6-2] HOLE TRANSPORT-RELATED LAYER

The hole transport layer or the hole injection/transport layer can be made of a known hole transport material.

The hole transport material may be selected from N,N′-diphenyl-N,N′-bis(3-methylphenyl)-1,1′-diphenyl-4,4′-diamine, N,N′-diphenyl-N,N′-bis(4-methylphenyl)-1,1′-diphenyl-4,4′-diamine, N,N′-diphenyl-N,N′-bis (1-naphthyl)-1,1′-diphenyl-4,4′-diamine, N,N′-diphenyl-N,N′-bis(2-naphthyl)-1,1′-diphenyl-4,4′-diamine, N,N,N′,N′-tetra(4-methylphenyl)-1,1′-bis(3-methylphenyl)-4,4′-diamine, N,N′-diphenyl-N,N′-bis(3-methylphenyl)-1,1′-bis(3-methylphenyl)-4,4′-diamine, N,N′-bis(N-carbazolyl)-1,1′-diphenyl-4,4′-diamine, 4,4′,4″-tris(N-carbazolyl)triphenylamine, N,N′,N″-triphenyl-N,N′,N″-tris(3-methylphenyl)-1,3,5-tri(4-aminophenyl)benzene, and 4,4′,4″-tris[N,N′,N″-triphenyl-N,N′,N″-tris(3-methylphenyl)]triphenylamine. Also, two or more among these materials may be used in a mixed form.

The hole transport layer or the hole injection/transport layer may be formed by vapor deposition of the above-exemplified hole transport material or may be formed by an application method such as a dip coating method or a spin coating method using a solution of the above compound or a solution of above compound and appropriate resin. If the hole transport layer or hole injection/transport layer is formed by vapor deposition, the thickness may be in a range from about 1 nm to about 500 nm. If the hole transport layer or the hole injection/transport layer is formed by an application method, the thickness may be in a range from about 5 nm to about 1000 nm.

As the thickness of the hole transport layer or the hole injection/transport layer increases, the voltage applied thereto for light emission must be increased, and therefore the luminous efficiency lowers so that the organic electro-luminescence element is likely to deteriorate. As the thickness decreases, the luminous efficiency increases, but the breakdown is likely to occur so that the lifetime of the organic electro-luminescence element becomes short. Accordingly, the thickness may be determined in the foregoing range in view of the luminous efficiency and the lifetime of the element.

The hole injection layer may be formed by vapor deposition of the hole injection material or may be formed by an application method such as a dip coating method or a spin coating method using a solution of the hole injection material or a solution of the hole injection material and appropriate resin. If the hole injection layer is formed by vapor deposition, the thickness may be in a range from about 1 nm to about 20 nm. If the hole injection layer is formed by an application method, the thickness may be in a range from about 1 nm to about 50 nm.

By employing the hole injection layer, the luminous efficiency is improved, and a leak current in a minute portion of the positive electrode interface can be effectively prevented so that occurrence of a dark spot can be prevented, and thereby the lifetime of the electro-luminescence element can be increased.

The hole injection material for forming the hole injection layer may be selected from porphorin ring compounds such as copper-phthalocyanine; indanthrene pigment; carbon membrane; electroconductive polymer membranes such as polyaniline and polythiophene; star-burst type compounds such as 4,4′,4″-tris(N-carbazolyl)triaminotriphenylamine, N,N′,N″-triphenyl-N,N′,N″-tris(3-methylphenyl)-1,3,5-tri(4-aminophenyl)benzene and 4,4′,4″-tris[N,N′,N″-triphenyl-N,N′,N″-tris(3-methylphenyl)]-triaminotriphenylamine.

### [6-3] ORGANIC LUMINESCENT LAYER

The organic luminescent layer may be made of a known organic luminescent material.

For example, the organic luminescent material may be selected from epindolidione, 2,5-bis[5,7-di-t-pentyl-2-benzoxazolyl]thiophene, 2,2′-(1,4-phenylenedivinylene)bisbenzothiazole, 2,2′-(4,4′-biphenylene)bisbenzothiazole, 5-methyl-2-{2-[4-(5-methyl-2-benzoxazolyl)phenyl]vinyl}benzoxazole, 2,5-bis(5-methyl-2-benzoxazolyl) thiophene, anthracene, naphthalene, phenanthrene, pyrene, chrysene, perylene, perynone, 1,4-diphenylbutadiene, tetraphenylbutadiene, coumarin, acrydine, stilbene, 2-(4-biphenyl)-6-phenylbenzoxazole, aluminum trisoxine, magnesium bisoxine, zinc bis(benzo-8-quinolinol), bis(2-methyl-8-quinolinol)aluminum oxide, indium trisoxine, aluminum tris(5-methyloxine), lithium oxine, gallium trisoxine, calcium bis(5-chloroxine), poly zinc bis(8-hydroxy-5-quinolinolyl)methane, dilithium epindolidione, zinc bisoxine, 1,2-phthaloperynone, 1,2-naphthaloperynone, polyphenylenevinylene compound, and so on.

Also, the organic luminescent material may be selected from conventional fluorescent dyes such as fluorescent coumarin dye, fluorescent perylene dye, fluorescent pyran dye, fluorescent thiopyran dye, fluorescent polymethine dye, fluorescent merocyanine dye and fluorescent imidazole dye. Among them, the chelated oxynoide compound is preferable.

The organic luminescent layer may be formed of a single layer of the foregoing fluorescent material, or may be formed of multiple layers of fluorescent material for controlling the characteristics such as a color and an intensity of the emitted light. Two or more kinds of fluorescent materials or substances may be mixed to form the organic luminescent layer. Also, the foregoing organic luminescent material may be doped with the luminescent material (e.g., fluorescent dyes such as rubrene, coumarin, quinacridone and quinacridone derivatives).

The organic luminescent layer may be formed by vapor deposition of the foregoing organic luminescent material, or may be formed by an application method such as a dip coating method or a spin coating method using a solution of the organic luminescent material or a solution of the organic luminescent material and appropriate resin. In the case where the organic luminescent layer is formed by vapor deposition, the thickness thereof may be in a range from about 1 nm to about 500 nm. If the organic luminescent layer is formed by an application method, the thickness may be in a range from about 5 nm to about 1000 nm.

As the thickness of the organic luminescent layer increases, the voltage applied thereto for light emission must be increased, and therefore the luminous efficiency lowers so that the organic electro-luminescence element is likely to deteriorate.

As the thickness of the organic luminescent layer decreases, the luminous efficiency increases, but the breakdown is likely to occur so that the lifetime of the organic electro-luminescence element becomes short. Accordingly, the thickness may be determined in the foregoing range in view of the luminous efficiency and the lifetime of the element.

### [6-4] ELECTRON TRANSPORT-RELATED LAYER

The electron transport layer or electron injection/transport layer may be made of a known electron transport material.

For example, the electron transport material may be selected from 2-(4-biphenylyl)-5-(4-tert-butylphenyl)-1,3,4-oxadiazole, 2-(1-naphthyl)-5-(4-tert-butylphenyl)-1,3,4-oxadiazole, 1,4-bis{2-[5-(4-tert-butylphenyl)-1,3,4-oxadiazolyl]}benzene, 1,3-bis{2-[5-(4-tert-butylphenyl)-1,3,4-oxadiazolyl]}benzene, 4,4′-bis{2-[5-(4-tert-butylphenyl)-1,3,4-oxadiazolyl]}biphenyl, 2-(4-biphenylyl)-5-(4-tert-butylphenyl)-1,3,4-thiadiazole, 2-(1-naphthyl)-5-(4-tert-butylphenyl)-1,3,4-thiadiazole, 1,4-bis{2-[5-(4-tert-butylphenyl)-1,3,4-thiadiazolyl]}-benzene, 1,3-bis(2-[5-(4-tert-butylphenyl)-1,3,4-thiadiazolyl]}benzene, 4,4′-bis{2-5-(4-tert-butylphenyl)-1,3,4-thiadiazolyl]}biphenyl, 3-(4-biphenylyl)-4-phenyl-5-(4-tert-butylphenyl)-1,2,4-triazole, 3-(1-naphthyl)-4-phenyl-5-(4-tert-butylphenyl)-1,2,4-triazole, 1,4-bis{3-[4-phenyl-5-(4-tert-butylphenyl)-1,2,4-triazolyl]}benzene, 1,3-bis{2-[1-phenyl-5-(4-tert-butylphenyl)-1,3,4-oxadiazolyl]}-benzene, 4,4′-bis{2-[1-phenyl-5-(4-tert-butylphenyl)-1,3,4-oxadiazolyl]}biphenyl, 1,3,5-tris{2-[5-(4-tert-butylphenyl)-1,3,4-oxadiazolyl]}benzene, 1,3-bis{3-[4-phenyl-5-(4-tert-butylphenyl)-1,3,4-oxadiazolyl]}benzene, 4,4′-bis{2-[4-phenyl-5-(4-tert-butylphenyl)-1,3,4-oxadiazolyl]}biphenyl, 1,3-bis{2-[1-phenyl-5-(4-tert-butylphenyl)-1,3,4-triazolyl]}benzene, and 4,4′-bis{2-[1-phenyl-5-(4-tert-butylphenyl)-1,3,4-triazolyl]}biphenyl. These materials can be used either alone or in combination. Among organic luminescent materials, those having relatively high electron transport ability such as aluminum trisoxine can be used.

The electron transport layer or electron injection/transport layer may be formed by vapor deposition of the foregoing electron transport material, or may be formed by an application method such as a dip coating method or a spin coating method using a solution of the electron transport material or a solution of the electron transport material and appropriate resin. In the case where the electron transport layer or electron injection/transport layer is formed by vapor deposition, the thickness thereof may be in a range from about 1 nm to about 500 nm. If the electron transport layer or electron injection/transport layer is formed by an application method, the thickness may be in a range from about 5 nm to about 1000 nm.

As the thickness of the electron transport layer or electron injection/transport layer increases, the voltage applied thereto for light emission must be increased, and therefore the luminous efficiency lowers so that the organic electro-luminescence element is likely to deteriorate. As the thickness of the electron transport layer or electron injection/transport layer decreases, the luminous efficiency increases, but the breakdown is likely to occur so that the lifetime of the organic electro-luminescence element becomes short. Accordingly, the thickness may be determined in the foregoing range in view of the luminous efficiency and the lifetime of the element.

The electron injection material for forming the electron injection layer may preferably be a material providing a small work function of the electron injection layer itself, and may be selected from aluminum, indium, magnesium, calcium, titanium, yttrium, lithium, gadolinium, ytterbium, ruthenium, manganese and alloys of these metals.

The electron injection material for forming the electron injection layer may be selected from an oxide of alkali metal or alkaline earth metal, a halogenide of alkali metal or alkaline earth metal (e.g., fluoride), a silicate compound of alkali metal or alkaline earth metal, an organic metal salt containing alkali metal or alkaline earth metal as the metal, an organic metal complex containing alkali metal or alkaline earth metal as the metal.

Alkali metals or alkaline earth metals contained in the above oxide, halogenide, organic metal salt or the organic metal complex may be lithium, beryllium, sodium, magnesium, potassium, calcium, rubidium, barium, strontium or cesium. In particular, lithium, magnesium, potassium, calcium and cesium are preferable because of good electron injection ability. The metal oxide, metal fluoride, organic metal salt and organic metal complex of these metals may be used.

The above organic metal salt or organic metal complex may be selected from acetylacetonate complex, ethylenediamine complex, glycine complex, oxine complex, alpha-nitroso-beta-naphthol complex, salicylic acid salt, salicylaldoxime complex, cupferron complex, benzoinoxime complex, bipyridine complex, phenanthroline complex, crown complex, proline complex, benzoylacetone complex, dicarboxylic acid salt and aliphatic carboxylic acid salt containing the above metal.

Among them, acetylacetonate complex, oxine complex, salicylic acid salt, salicylaldoxime complex, dicarboxylic acid salt and aliphatic carboxylic acid salt containing the above metal are preferable because of good electron injection ability.

The electron injection layer may be formed by vapor deposition, sputtering method or the like. When the electron injection layer is formed by vapor deposition, the thickness thereof may be in a range from about 0.1 nm to about 20 nm. As the thickness of the electron injection layer decreases, the electron injection efficiency increases. However, if the thickness lowers below the above range, it causes the non-uniformity of electron injection and dark spots. If the thickness is higher than the above range, the luminous efficiency is poor and the lifetime of the element becomes short. Accordingly, in view of the luminous efficiency and the lifetime of the organic electro-luminescence element, the thickness may be determined within the foregoing range.

[7] Description is now given on the embodiments each reflecting at least one aspects of the present invention with reference to the accompanying drawings.

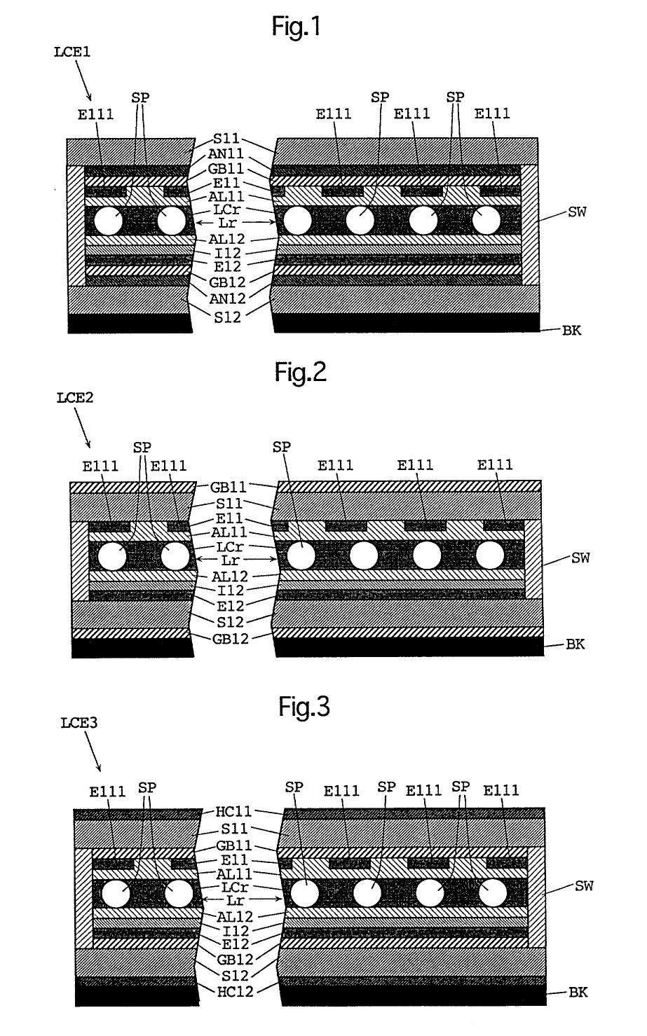

FIG. 1 is a schematic section view showing an example of the liquid crystal element according to the present invention.

In this example, a liquid crystal element LCE1 shown in FIG. 1 is utilized as a display element of a reflection type, and the displayed image of this display element is observed from an upper side of the liquid crystal element LCE1 in FIG. 1.

As will be described later in greater detail, the liquid crystal element LCE1 includes a liquid crystal LCr having a selective reflection wavelength in a red region. The liquid crystal element LCE1 is used for red display in this example.

The liquid crystal element LCE1 has a pair of substrates S11 and S12, and a liquid crystal layer Lr held between the substrates. A black light absorbing layer BK is arranged on the outer side of the substrate S12, which is located on the side remote from the observation side.

In this example, the substrates S11 and S12 are transparent film substrates made of a resin, respectively. The substrates S11 and S12 are made of polycarbonate in this example.

An anchor layer AN11, a gas barrier layer GB11, a transparent electrode E11, and an orientation film (alignment film) AL11 are successively formed on the substrate S11.

The electrode E11 is made of an amorphous oxide comprising indium (In), zinc (Zn) and oxygen (O) as essential constituent elements. Hereinafter, the material termed “amorphous oxide comprising indium (In), zinc (Zn) and oxygen (O) as essential constituent elements” may be referred to as “IZO”. The electrode E11 is formed of a plurality of belt-like electrode portions E111 with a predetermined width, which are parallel to each other with a predetermined space therebetween.

The IZO electrode may be formed, for example, by uniformly forming an IZO film on the substrate and then patterning the IZO film by a photolithography method, etching method or other methods into the above-mentioned configurations. The IZO film may be made typically by a sputtering method. The IZO film can be formed by an ion plating method, a coating thermal decomposition method, a vacuum deposition method, a CVD method or others. The IZO film may be about 20 nm to about 300 nm in thickness.

The gas barrier layer GB11 is provided for preventing the entry of water and oxygen (O₂) into the liquid crystal layer Lr and others. The gas barrier layer GB11 is composed of SiOₓ (silica) wherein x is a real number which fulfills the relation of 0<x≦2. Al₂O₃ (alumina) may be used as the material for the gas barrier layer instead of SiOₓ.

The anchor layer AN11 is arranged, as described above, between the gas barrier layer GB11 and the substrate S11 for increasing the adhesion of the gas barrier layer GB11 to the substrate S11. The anchor layer AN11 is made of urethane resin in this example. An acrylic resin may be used as the material for the anchor layer in place of urethane resin.

The orientation film AL11 is provided for controlling the oriented state of liquid crystal molecules in the liquid crystal layer Lr. The orientation film AL11 may be made of, e.g. polyimide-containing material.

On the other substrate S12, an anchor layer AN12, a gas barrier layer GB12, a transparent electrode E12, an insulating film (insulating layer) I12 and an orientation film AL12 are successively formed in this order.

The electrode E12 is made, like the electrode E11, of IZO, i.e., the amorphous oxide comprising indium, zinc and oxygen as essential constituent elements. The electrode E12 is formed of, like the electrode E11, a plurality of belt-like electrode portions although not illustrated, which are parallel to each other with a predetermined space therebetween. The belt-like electrode portions of the electrode E12 extend across the belt-like electrode portions E111 of the electrode E11 so that these belt-like electrode portions form the so-called matrix structure.

The anchor layer AN12, gas barrier layer GB12 and orientation film AL12 are provided on the substrate S12 for the same purposes as the anchor layer AN11, gas barrier layer GB11 and orientation film AL11 on the substrate S11, respectively.

The insulating film I12 is provided for keeping electrical insulation between the electrodes E11 and E12. The insulating film may be, e.g. an inorganic film made of silicon oxide or others, or an organic film made of polyimide resin, epoxy resin or others. In the liquid crystal element LCE1, the insulating film is arranged only on one (i.e. substrate S12) of the paired substrates S11 and S12 for holding the liquid crystal layer therebetween. However, the insulating film may be arranged on both of the paired substrates.

As described above, the liquid crystal layer Lr is arranged between the substrates S11 and S12, on each of which the electrode, gas barrier layer and others are formed.

The liquid crystal layer Lr in this example includes the liquid crystal LCr and spherical spacers SP.

The spacers SP are arranged between the substrates (strictly speaking, between the orientation films) for controlling the thickness of the liquid crystal. The spacers may be preferably formed of particles, which are formed of a hard material having a sufficient deformation resistance against heat and pressure. The spacers may be made of, e.g., an inorganic material such as finely divided glass fibers, silicate glass in the ball-like form or alumina powder, or spheric synthetic particles of an organic material such as divinylbenzene-containing cross-linked polymer or polystyrene-containing cross-linked polymer.

For preventing leakage of the liquid crystal LCr from the peripheral portions of the substrates, a seal wall SW made of a resin material is arranged at the peripheral portion of the substrate. The seal wall SW is provided between the substrates and has an annular or frame-like form.

The liquid crystal LCr in this example is a chiral nematic liquid crystal composition exhibiting the cholesteric phase at room temperature. This chiral nematic liquid crystal composition includes a nematic liquid crystal composition and a chiral material added thereto for obtaining an intended helical pitch, and more specifically for having an intended selective reflection wavelength. By adjusting the amount of chiral material added to the nematic liquid crystal composition, the selective reflection wavelength of the chiral nematic liquid crystal composition can be adjusted. The selective wavelength of the liquid crystal LCr is set in the red region in this example.

When the liquid crystal composition exhibiting the cholesteric phase is in a planar state wherein the helical axes are perpendicular to the substrate, the liquid crystal composition selectively reflects the light of a wavelength corresponding to a product of a helical pitch and an average refractive index of the liquid crystal composition. Accordingly, the liquid crystal composition in the planar state exhibits a color corresponding to the selective reflection wavelength if the selective reflection wavelength is in the visible range. By setting the selective reflection wavelength, e.g., in an infrared range, the liquid crystal composition in the planar state looks transparent.

The liquid crystal composition exhibiting the cholesteric phase scatters the light when the liquid crystal composition is in a focal conic state wherein the helical axes are oriented irregularly. Due to this scattering, the liquid crystal composition in the focal conic state looks opaque when the helical pitch is larger than the visible light wavelength. If the helical pitch is short in such a case where the selective reflection wavelength is in the visible range, the scattering does not occur to a large extent and the liquid crystal composition in the focal conic state exhibits a nearly transparent appearance.

Accordingly, by changing the state of the liquid crystal composition between the planar state and the focal conic state, the liquid crystal composition exhibiting the cholesteric phase assumes, e.g., the selective reflection state (planar state) or the transparent state (focal conic state). If the selective reflection wavelength is in the infrared range, the liquid crystal composition exhibiting the cholesteric phase assumes, e.g., the transparent state (planar state) or the opaque state (focal conic state) by changing the state of the liquid crystal composition between the planar state and the focal conic state. The liquid crystal composition exhibiting the cholesteric phase can assume a state where the planar state and the focal conic state are mixed.

The state of the liquid crystal (liquid crystal composition) LCr can be changed by applying a voltage across the electrodes E11 and E12. For example, the liquid crystal LCr can assume the planar state when a relatively high voltage is applied across the electrodes. When a relatively low voltage is applied across the electrodes, the liquid crystal LCr can assume the focal conic state. By applying an intermediate voltage across the electrodes, the liquid crystal LCr can assume the state where the planar state and the focal conic state are mixed. After stop of application of the voltage, each of these states of the liquid crystal is stably held.

The selective reflection wavelength of the liquid crystal LCr is set in the red wavelength region, as already described. Accordingly, when the liquid crystal LCr is in the planar state, the liquid crystal LCb selectively reflects the light in the red wavelength range, and exhibits a red appearance. When the liquid crystal LCr is in the focal conic state, the liquid crystal LCb becomes transparent. Therefore, the liquid crystal LCr can perform red display. The manner of driving the liquid crystal element LCE1 will be described later.

In the liquid crystal element LCE1 of the present invention, IZO is used as the material for electrodes as stated above. IZO is not crystallized in a high-temperature environment and is highly rigid, so that a problem such as cracks and the like in the electrode is unlikely to arise during the production of the element. Even if the IZO electrode is formed on the resin film substrate, the problem of cracks or the like in the electrode would be unlikely to be involved in the course of manufacturing the element. When IZO is used as the material for electrodes, the electrode would be more unlikely to break due to cracks created during the production of the element than when ITO is used as the material for electrodes, as shown in the experimental results given later. Consequently the liquid crystal element LCE1 can be produced in a higher yield.

Since IZO can have a relatively low resistance, the drive voltage is not increased. IZO can have a high light transmittance of 80% or more so that the transparency of the element is not deteriorated.

Because the gas barrier layers GS11, GS12 are formed on the substrates S11, S12 holding the liquid crystal layer Lr therebetween, the entry of water and oxygen into the liquid crystal layer Lr can be suppressed. Therefore the degradation of liquid crystal layer Lr (liquid crystal LCr) can be suppressed, whereby the liquid crystal element LCE1 is allowed to provide good display for a long term. This can preclude the display quality of the liquid crystal element LCE1 from lowering with time even when the liquid crystal element LCE1 is subjected to a high temperature/high humidity environment.

The gas barrier layers GS11, GS12 are arranged on the outer side of the IZO electrodes E11, E12, so that the deterioration of the electrode due to water or oxygen can be suppressed. Accordingly the display driving can be stably performed by application of a voltage across the electrodes for a long term.

The anchor layers AN11, AN12 are arranged between the substrates S11, S12 and the gas barrier layers GS11, GS12 made of inorganic materials (SiOₓ in this example), respectively, so that the adhesion of each gas barrier layer to each substrate can be increased and the release or peel of gas barrier layers from the substrates can be suppressed. Thereby the gas barrier layers can achieve a long-term function of preventing the entry of water and oxygen. As a result, the degradation of liquid crystal layer Lr can be suppressed for a longer period, resulting in that a longer-term good display can be performed by the liquid crystal element LCE1.

[8] FIG. 2 is a schematic section view showing another example of the liquid crystal element according to the present invention.

The following layers are formed on the resin substrates S11, S12 holding the liquid crystal layer Lr therebetween in the liquid crystal element LCE2 shown in FIG. 2.

The gas barrier layer GB11 is formed on the surface, remote from the liquid crystal layer Lr, of the substrate S11. The IZO transparent electrode E11 and orientation film AL11 are formed successively in this order on the surface, near to the liquid crystal layer Lr, of the substrate S11.

The gas barrier layer GB12 is formed on the surface, remote from the liquid crystal layer Lr, of the substrate S12. The IZO transparent electrode E12, insulating film I12 and orientation film AL12 are formed successively in this order on the surface, near to the liquid crystal layer Lr, of the substrate S12.

IZO is used as the material for the electrode in the liquid crystal element LCE2 as in the liquid crystal element LCE1. Therefore a problem of cracks or the like in the electrode would be unlikely to arise, making it possible to produce the liquid crystal element LCE2 in a higher yield.

The provision of the gas barrier layers GB11, GB12 can suppress the deterioration of the liquid crystal layer Lr and the electrodes due to water and oxygen.

In the liquid crystal element LCE2, the anchor layers may be formed between the gas barrier layers GB11, GB12 and the substrates S11, S12, respectively to increase the adhesion of each of the gas barrier layers GB11, GB12 to each of the substrates S11, S12 as in the liquid crystal element LCE1.

[9] FIG. 3 is a schematic section view showing a further example of the liquid crystal element according to the present invention.

The following layers are formed on the resin substrates S11, S12 holding the liquid crystal layer Lr therebetween in the liquid crystal element LCE3 shown in FIG. 3.

A hard coat layer HC11 for preventing the marring of the substrate is formed on the surface, remote from the liquid crystal layer Lr, of the substrate S11. The hard coat layer may be made of, for example, thermosetting epoxy resin, UV-curing acrylic resin or others. The hard coat layer can be easily formed, e.g. by an application method using these materials. The thickness of the hard coat layer may be in a range, e.g., from about 0.5 μm to about 5 μm.

The gas barrier layer GB11, IZO transparent electrode E11 and orientation film AL11 are formed successively in this order on the surface, near to the liquid crystal layer Lr, of the substrate S11.

A hard coat layer HC12 is formed on the surface, remote from the liquid crystal layer Lr, of the substrate S12. The gas barrier layer GB12, IZO transparent electrode E12, insulating film I12 and orientation film AL12 are formed successively in this order on the surface, near to the liquid crystal layer Lr, of the substrate S12.

IZO is used as the material for electrodes in the liquid crystal element LCE3 similar to the liquid crystal element LCE1. Therefore, a problem of cracks or the like occurring in the electrode would be unlikely to arise, making it possible to produce the liquid crystal element LCE3 in a higher yield.

The provision of the gas barrier layers GB11, GB12 can suppress the deterioration of the liquid crystal layer Lr and the electrodes due to water and oxygen.

In the liquid crystal element LCE3, the hard coat layers HC11, HC12 are formed on the outer side of the substrates to protect the substrate against marring. Therefore it is possible to suppress the lowering of display quality due to marring of the substrate, thereby ensuring a long-term good display. The hard coat layer HC12 may be formed on the outermost side instead of forming the light absorbing layer BK on the outermost side.

In the liquid crystal element LCE3, the anchor layers may be formed between the gas barrier layers GB11, GB12 and the substrates S11, S12, respectively to increase the adhesion of the gas barrier layers GB11, GB12 to the substrates S11, S12, respectively as in the liquid crystal element LCE1.

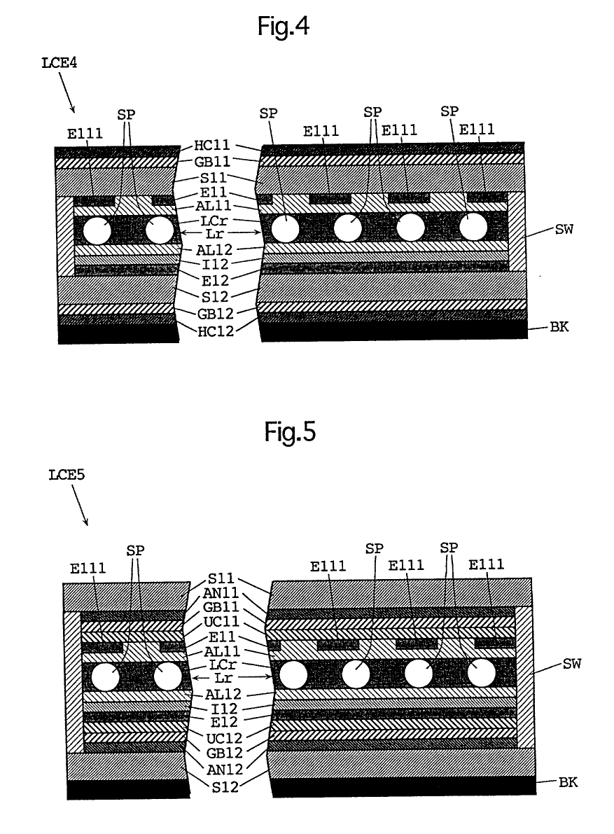

In the liquid crystal element LCE1, a hard coat layer may be formed on the outer side of the substrate as in the liquid crystal element LCE3. The same effect can be achieved.

[10] FIG. 4 is a schematic section view showing a still further example of the liquid crystal element according to the present invention.

The liquid crystal element LCE4 shown in FIG. 4 is equivalent to the liquid crystal element LCE2 shown in FIG. 2 except that hard coat layers are formed on the outer sides of the substrates in the liquid crystal element LCE4.

Stated more specifically, the following layers are formed on the resin substrates S11, S12 holding the liquid crystal layer Lr therebetween in the liquid crystal element LCE4.

The gas barrier layer GB11 and the hard coat layer HC11 are arranged in this order on the surface, remote from the liquid crystal layer Lr, of the substrate S11. The IZO transparent electrode E11 and the orientation film AL11 are formed successively in this order on the surface, near to the liquid crystal layer Lr, of the substrate S11.

The gas barrier layer GB12 and the hard coat layer HC12 are arranged in this order on the surface, remote from the liquid crystal layer Lr, of the substrate S12. The IZO transparent electrode E12, insulating film I12 and orientation film AL12 are formed successively in this order on the surface, near to the liquid crystal layer Lr, of the substrate S12.

The liquid crystal element LCE4 has the advantages mentioned above in respect of the liquid crystal element LCE2. In the liquid crystal element LCE4, it is possible to suppress the marring of the substrate surface because of the hard coat layers HC11, HC12 provided on the outside of the substrates S11, S12, respectively, similar to the liquid crystal element LCE3.

In the liquid crystal element LCE4, similar to the liquid crystal element LCE1, anchor layers may be provided between the gas barrier layers GB11, GB12 and the substrates S11, S12, respectively to increase the adhesion of the gas barrier layers GB11, GB12 to the substrates S11, S12, respectively.

[11] An undercoat layer may be provided between the electrode and the resin substrate for increasing the adhesion of the electrode to the substrate in any of liquid crystal elements described above as in a liquid crystal element LCE5 shown in FIG. 5.

The liquid crystal element LCE5 of FIG. 5 is identical with the liquid crystal element LCE1 of FIG. 1 except that the undercoat layer is provided between the electrode and the substrate in the element LCE5.

Stated more specifically, in the liquid crystal element LCE5, the following layers are formed on the resin substrates S11, S12 holding the liquid crystal layer Lr therebetween.

The anchor layer AN11, gas barrier layer GB11, undercoat layer UC11, IZO transparent electrode E11 and orientation film AL11 are arranged in this order on the surface, near to the liquid crystal Lr, of the substrate S11.

The anchor layer AN12, gas barrier layer GB12, undercoat layer UC12, IZO transparent electrode E12, insulating film I12 and orientation film AL12 are formed successively in this order on the surface, near to the liquid crystal layer Lr, of the substrate S12.

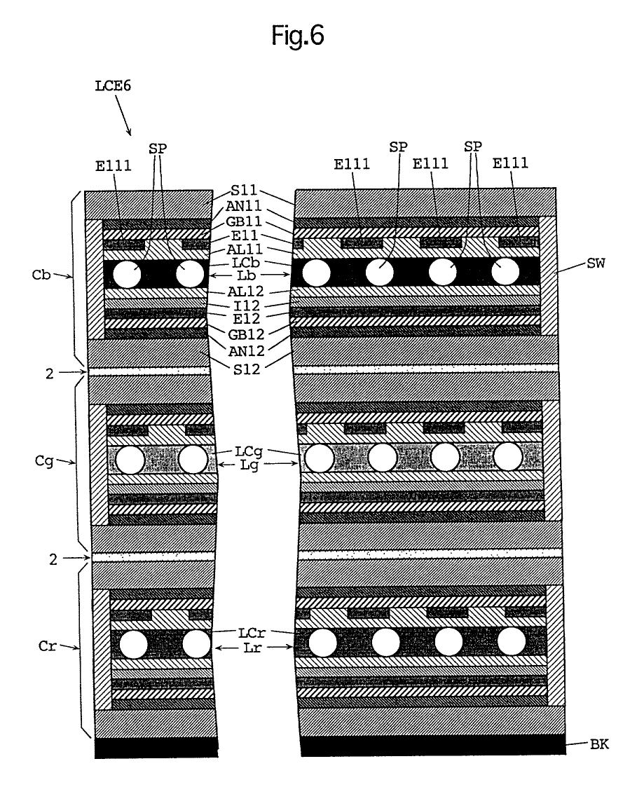

The liquid crystal element LCE5 has the advantages described above in respect of the liquid crystal element LCE1. Further it is possible to increase the adhesion of the electrode to the substrate by the provision of the undercoat layers UC11, UC12, so that the display can be stably provided by application of a voltage across the electrodes E11, E12 for a long term.

[12] FIG. 6 is a schematic section view showing an example of the layered type liquid crystal element according to the present invention.

The layered type liquid crystal element LCE6 shown in FIG. 6 has three liquid crystal cells Cb, Cg and Cr layered on each other.

The layered type liquid crystal element LCE6 in this example is utilized as a display element of the reflection type, and a displayed image of this display element is observed from the outside of the liquid crystal cell Cb (an upper side of the liquid crystal cell Cb in FIG. 6). Namely the liquid crystal cell Cb is arranged in a position closest to the observation side and the liquid crystal cell Cr is arranged in a position remotest from the observation side. A black light absorbing layer BK is provided on the outer side of the liquid crystal cell Cr which is provided in a position remotest from the observation side. The layered type liquid crystal element LCE6 can give a display in multiple colors as will be described later in detail.

Each of the liquid crystal cells Cb, Cg, Cr has the same structure as the liquid crystal element LCE1 shown in FIG. 1 except that the light absorbing layer BK is removed in each of the liquid crystal cells.

The liquid crystal cells Cb, Cg and Cr are provided for blue display, green display and red display, respectively, and have liquid crystal layers Lb, Lg, Lr, respectively. The liquid crystal layers Lb, Lg, Lr include liquid crystals LCb, LCg, LCr, respectively having a selective reflection wavelength in the blue wavelength region, green wavelength region and red wavelength region, respectively. The liquid crystals LCb, LCg, LCr in this example are chiral nematic liquid crystal compositions exhibiting the cholesteric phase at room temperature.

In the liquid crystal cell Cb, the liquid crystal layer Lb is held between a pair of resin substrates S11 and S12 similar to the liquid crystal element LCE1 of FIG. 1. Gas barrier layers and others are formed on the substrates S11 and S12 of the liquid crystal cell Cb similar to the liquid crystal element LCE1 of FIG. 1.

Stated more specifically, the anchor layer AN11, gas barrier layer GB11, IZO transparent electrode E11 and orientation film AL11 are formed successively in this order on the substrate S11. Likewise, the anchor layer AN12, gas barrier layer GB12, IZO transparent electrode E12, insulating film I12 and orientation film AL12 are formed successively in this order on the substrate S12.

The liquid crystal cell Cg has the same structure as the liquid crystal cell Cb except that the liquid crystal layer Lg has a different liquid crystal. The liquid crystal cell Cr has the same structure as the liquid crystal cell Cb except that the liquid crystal layer Lr has a different liquid crystal.

Two adjacent liquid crystal cells are adhered to each other with an adhesive layer 2 interposed therebetween. The adhesive layer 2 is a double-sided adhesive tape in this example. The double-sided adhesive tape may include, for example, an acrylic adhesive. The adhesive layer 2 may be composed of, e.g. an adhesive instead of the double-sided adhesive tape. The adhesive may be UV-curing resin, thermosetting silicone adhesive or others.

The layered type liquid crystal element LCE6 in which the liquid crystal cells Cb, Cg, Cr (liquid crystal layers Lb, Lg, Lr) are layered together can provide blue, green and red displays, respectively, a display of intermediate colors among these colors, a display of a mixture of 2 or 3 colors among these colors, and thus a multicolor or fullcolor display. When the liquid crystals of all liquid crystal cells (liquid crystal layers) are in the transparent state, the element LCE6 exhibits the black color of the light absorbing layer BK provided on the outside of the liquid crystal cell Cr. The method of driving the layered type liquid crystal element LCE6 will be described later.

The same effects as those of the liquid crystal element LCE1 of FIG. 1 is achieved in the layered type liquid crystal element LCE6.

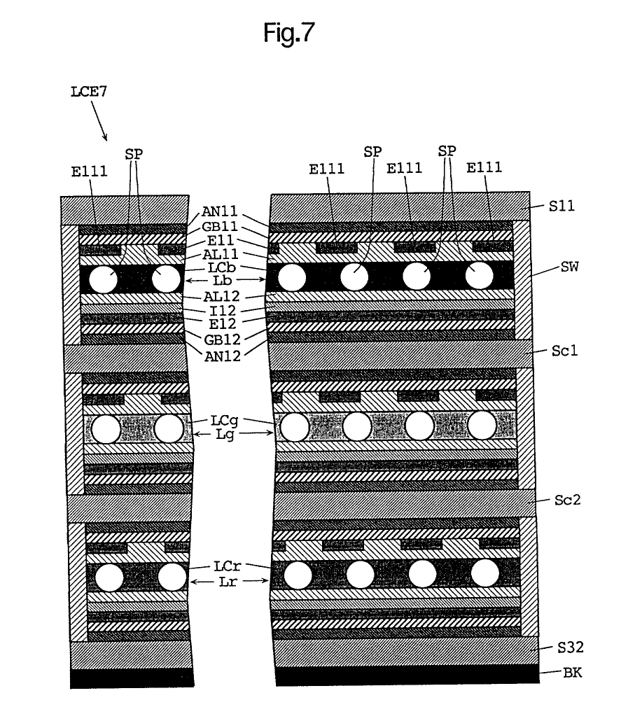

The layered type liquid crystal element LCE6 has a structure in which, as mentioned above, three liquid crystal element LCE1 of FIG. 1 are layered (strictly speaking, a structure in which three liquid crystal element LCE1 from each of which the light absorbing layer BK is excluded are layered). A layered type liquid crystal element may be made by layering other liquid crystal elements described above (e.g. the liquid crystal elements LCE2-LCE5) than the liquid crystal element LCE1. In the layered type liquid crystal element thus obtained, the effect achieved thereby corresponds to the layers formed on the substrates of layered liquid crystal elements (liquid crystal cells). The layered type liquid crystal element may be made by layering two or more liquid crystal elements of different structures (e.g. liquid crystal elements LCE1 and LCE2).

[13] In the layered type liquid crystal element of the invention, only one substrate may be arranged between adjacent two liquid crystal layers as in a layered type liquid crystal element LCE7 shown in FIG. 7, so that the single substrate may be utilized commonly to hold the adjacent two liquid crystal layers.

In the layered type liquid crystal element LCE7 of FIG. 7, a substrate Sc1 is arranged between the adjoining liquid crystal layers Lb, Lg while a substrate Sc2 is arranged between the adjoining liquid crystal layers Lg, Lr.

The liquid crystal layer Lb is held between the substrates S11 and Sc1. The liquid crystal layer Lg is held between the substrates Sc1 and Sc2. The liquid crystal layer Lr is held between the substrates Sc2 and S32. In other words, the substrate Sc1 is commonly used, e.g. for holding the liquid crystal layers Lb and Lg. Similarly the substrate Sc2 is commonly used, e.g. for holding the liquid crystal layers Lg and Lr.

In the layered type liquid crystal element LCE7, similar to the liquid crystal element LCE1 of FIG. 1, the anchor layer AN11, gas barrier layer GB11, IZO transparent electrode E11 and orientation film AL11 are formed successively in this order on the surface, opposed to the liquid crystal layer Lb, of the substrate S11.

The anchor layer AN12, gas barrier layer GB12, IZO transparent electrode E12, insulating film I12 and orientation film AL12 are formed successively in this order on the surface, opposed to the liquid crystal layer Lb, of the common substrate Sc1. The anchor layer, gas barrier layer, IZO transparent electrode and orientation film are formed successively in this order on the surface, opposed to the liquid crystal layer Lg, of the common substrate Sc1.

The anchor layer, gas barrier layer, IZO transparent electrode, insulating film and orientation film are formed successively in this order on the surface, opposed to the liquid crystal layer Lg, of the common substrate Sc2. The anchor layer, gas barrier layer, IZO transparent electrode and orientation film are formed successively in this order on the surface, opposed to the liquid crystal layer Lr, of the common substrate Sc2.

The anchor layer, gas barrier layer, IZO transparent electrode, insulating film and orientation film are formed successively in this order on the surface, opposed to the liquid crystal layer Lr, of the substrate S32.

The same effects as by the layered type liquid crystal element LCE6 are achieved by the layered type liquid crystal element LCE7.

The layered type liquid crystal element LCE7 as a whole can be thinner than the layered type liquid crystal element LCE6 because common substrates are used.

[14] In the liquid crystal element and layered type liquid crystal element according to the present invention, a resin structure (resin pillar-like structure) may be provided instead of, or in combination with, the spacers at the position between the substrates for holding the liquid crystal layer.

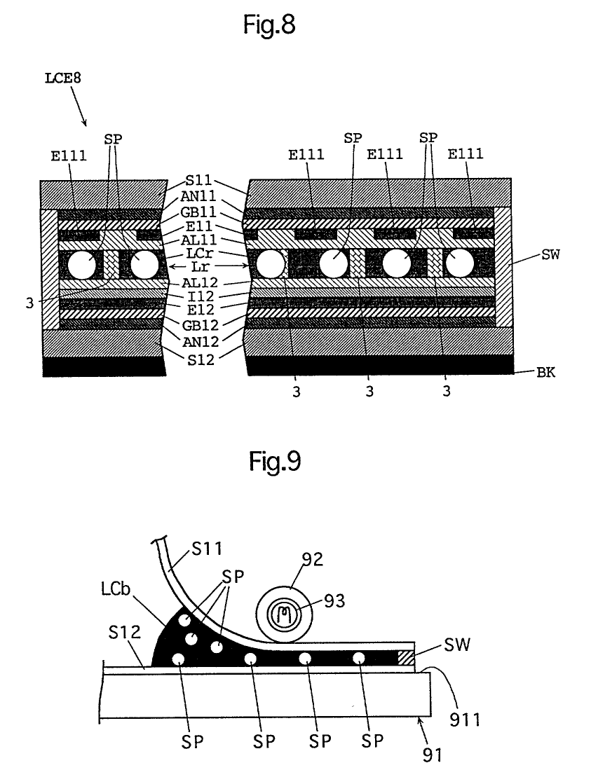

FIG. 8 is a schematic section view showing an example of the liquid crystal element having resin structures.

The liquid crystal element LCE8 of FIG. 8 is equivalent to the liquid crystal element LCE1 of FIG. 1 except that resin structures 3 are provided in the liquid crystal layer Lr of the element LCE8. The resin structure can be used for increasing the strength of the liquid crystal element or liquid crystal cell as a whole and for adhering together the paired substrates for holding the liquid crystal layer therebetween.

The resin structure may be made of a material which can be softened when heated, and can be solidified when cooled. An organic material which does not chemically react with the liquid crystal material and which has an appropriate elasticity is suitable as the material for the resin structure. The material for the resin structure may be, e.g. a thermoplastic polymer material. The thermoplastic polymer material useful for the resin structure may be, e.g. polyvinyl chloride resin, polyvinylidene chloride resin, polyvinyl acetate resin, polymethacrylic ester resin, polyacrylic ester resin, polystyrene resin, polyamide resin, polyethylene resin, polypropylene resin, fluorine-containing resin, polyurethane resin, polyacrylonitrile resin, polyvinyl ether resin, polyvinyl ketone resin, polyether resin, polyvinyl pyrrolidone resin, saturated polyester resin, polycarbonate resin, chlorinated polyether resin or the like. The resin structure may be formed of at least one of these materials.

The resin structure may have a dot-like columnar form having a circular, square or elliptic section, although not restricted thereto.

The resin structures within the display region may be arranged with a predetermined space therebetween, e.g., in a lattice form in accordance with a predetermined arrangement rule.

The dot-like resin structures may have sizes and pitches which are appropriately determined in accordance with the sizes of the liquid crystal element (liquid crystal display element) and the pixel resolution.

If the dot-like resin structure is arranged between the electrodes (substrates) with priority, the aperture ratio can be high.

It is preferable that the resin structures are arranged and disposed in a pattern other than a random pattern, which may be caused, e.g., by dispersion of the resin material. More specifically, it is preferable that the arrangement pattern of the resin structures is determined in accordance with appropriate arrangement rules for keeping an appropriate gap between the substrates, and not for impeding image display. In the preferable arrangement of the resin structures as described above, the resin structures may be equally spaced from each other, the resin structures may be spaced by a distance which gradually varies, or a predetermined pattern of arrangement of the resin structures may be repeated regularly. The resin structures may take the form of stripes spaced by a predetermined distance from each other.

[15] An example of the method for producing the layered type liquid crystal element LCE6 shown in FIG. 6 will now be described.

First, the respective liquid crystal cells Cb, Cg and Cr are formed. The liquid crystal cell Cb can be formed in the following manner.

For producing the liquid crystal cell Cb, the following layers are formed successively on the substrates S11, S12. The anchor layer AN11, gas barrier layer GB11, IZO transparent electrode E11 and orientation film AL11 are successively formed in this order on the substrate S11. Likewise, the anchor layer AN12, gas barrier layer GB12, IZO transparent electrode E12, insulating film I12 and orientation film AL12 are successively formed in this order on the substrate S12.

The anchor layer may be formed, e.g. by an application method and the gas barrier layer may be formed, e.g. by a sputtering method. The electrode can be formed by uniformly forming an IZO film on the substrate by a sputtering method or others, and then patterning the IZO film by a photolithography method and other method into predetermined configurations. The insulating film and the orientation film are formed by known methods such as a sputtering method, a spin coating method, a roll coating method or a vapor deposition method with an appropriate film-forming material.

Then, an annular wall is formed with a resin such as ultraviolet-curing resin or thermosetting resin on the peripheral portion of one of the substrates S11 and S12. The wall made of the resin will form the seal wall SW for preventing leakage of the liquid crystal. This resin wall can be formed by applying the resin onto the substrate from the end of a nozzle by a dispenser method or ink-jet method. The resin wall can be formed by a printing method using a screen or a metal mask. The resin wall can also be formed by a transfer method, in which a resin is supplied onto a flat plate or a roller, and then is transferred onto the substrate.

If the resin structures are provided as described hereinbefore, the resin structures, which have predetermined configurations and which are patterned into a predetermined arrangement form, are formed on one of the substrates (e.g. other than the substrate provided with the resin wall forming the seal wall). The resin structures can be formed by a printing method in which a resin material paste (prepared, e.g., by dissolving the resin into a solvent) is squeezed out by a squeegee via a screen, a metal mask or the like onto the substrate. The resin structures can be formed by a method such as a dispenser method or an ink jet method in which the resin material is supplied onto the substrate from the end of a nozzle, or a transfer method in which the resin material is supplied onto a flat plate or roller, and then is transferred onto the substrate. It is preferable that each of the resin structures at this time has a height larger than the desired thickness of the liquid crystal layer for adhering the substrates together with the resin structures to be arranged between the substrates.

Thereafter, the spacers SP are dispersed on the surface of at least one of the substrates S11 and S12 by a known method.

Then, a predetermined amount of droplets of the liquid crystal LCb is applied onto an end portion of one of the substrates.

Subsequently, the end portion of the other substrate is laid over the end portion of the substrate carrying the liquid crystal LCb, and both the substrates are overlaid together while spreading the liquid crystal from the above end portion toward the other end portion. When overlaying the substrates, heat and pressure are applied. For example, a fixing device shown in FIG. 9 is used for overlaying the substrates.

More specifically, the substrate carrying the liquid crystal is laid over a flat surface 911 of a substrate carrier member 91. The end portion of the other substrate is laid over the end portion of the substrate on the carrier member 91, and these substrates are overlaid together by a roller 92 internally provided with a heater 93. For example, the roller 92 is moved in a predetermined direction (leftward in FIG. 9) at a predetermined speed while pressing the roller 92 toward the substrates so that the heat of the heater 93 and the pressure by the roller 92 are applied to both substrates for overlaying and fixing them.

By overlaying the substrates together in the above manner, the liquid crystal cell can be produced with high accuracy even if the substrate is a flexible substrate such as a film substrate.

By applying the pressure and spreading the liquid crystal while overlaying the substrates, it is possible to suppress inclusion of mixed bubbles into the liquid crystal layer Lb.

If the seal wall is made of thermosetting resin, this can be hardened by the above heating. If the resin structures are made of a thermoplastic polymer material, the resin structures can be heated in the above manner, and then is cooled so that the resin structures are softened, and then are solidified, and thereby the resin structures can be adhered onto the opposite substrates. If the seal wall and/or the resin structures are made of materials having heat softening properties, the application of pressure is kept to push the substrates against each other until the material is cooled to a temperature lower than the softening temperature. If the seal wall is made of a photosetting resin, both substrates are overlaid, and then the seal wall material is hardened by light irradiation.

Thereby, the liquid crystal cell Cb of the structure shown in FIG. 6 can be produced. The liquid crystal cells Cg, Cr can be produced in a similar manner.

The three liquid crystal cells prepared in this manner are adhered together in the predetermined order by an adhesive material such as adhesives or double-sided adhesive tape, and the light absorbing layer BK is formed on the outer side of the liquid crystal cell Cr so that the layered type liquid crystal element LCE6 is completed.

Instead of dispersing the spacers on the substrate in advance, the spacers may be dispersed within the liquid crystal before being dropped onto the substrate. Even in this manner, the spacers can be arranged between the substrates, and the thickness of the liquid crystal can be adjusted.

Other liquid crystal elements and layered type liquid crystal elements described above can be produced in the manner similar to the above.

[16] Description will now be given on the method of driving the layered type liquid crystal element LCE6 of FIG. 6.

As described above, the electrodes of each liquid crystal cell have a matrix structure. Therefore, by performing simple matrix drive of each liquid crystal element, the desired characters, graphics and others can be displayed.

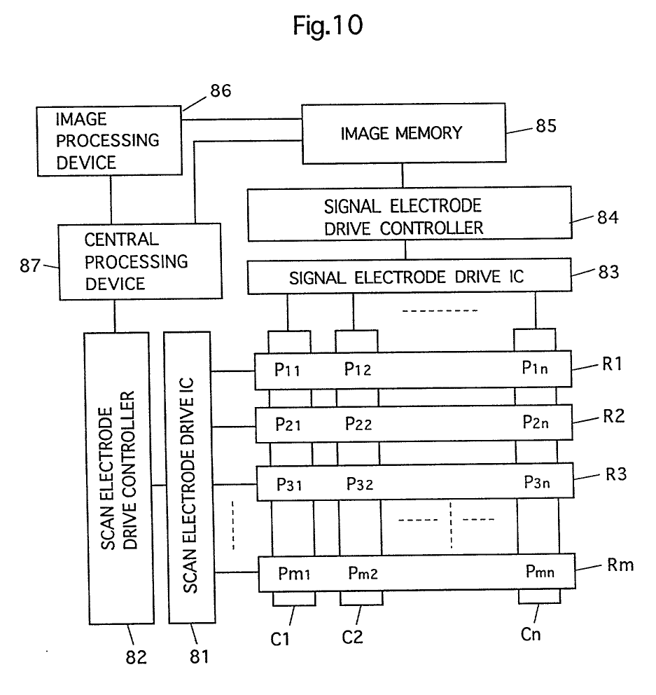

A manner of the simple matrix drive of the liquid crystal cell Cb will now be described with reference to FIG. 10.

In FIG. 10, signal electrodes (column electrodes) C1-Cn (n: natural number) correspond to the respective belt-like electrode portions E111 of the electrode E11 shown in FIG. 6. Scan electrodes (row electrodes) R1-Rm (m: natural number) correspond to the respective belt-like electrode portions of the electrode E12 in FIG. 6.

In the liquid crystal cell Cb, the orientation of the liquid crystal can be changed by the following region unit. This region unit has a cross region where one scan electrode and one signal electrode cross each other, and a peripheral region of the cross region. In the liquid crystal cell Cb, each pixel is formed of the cross region where one scan electrode and one signal electrode cross each other, and the peripheral region. The pixel at the position of the crossing between the scan and signal electrodes Rp and Cq is represented as a pixel Ppq, where p is a natural number satisfying a relationship of (1≦p≦m) and q is a natural number satisfying a relationship of (1≦q≦n).

The liquid crystal cell Cb can display an image based on the image data, which are written into an image memory 85 by an image processing device 86 and a central processing device 87, in the following manner.

The scan electrode drive IC 81 issues a select signal to one of the scan electrodes R1-Rm for setting it to the selected state, and issues non-selection signals to the others for setting them to the unselected state. The scan electrode drive IC 81 switches the electrode to be selected at a predetermined time interval, and the respective scan electrodes are successively set to the selected state. This control is performed by the scan electrode drive controller 82.

For rewriting the respective drive target pixels on the scan electrode in the selected state, the signal electrode drive IC 83 simultaneously issues signal voltages corresponding to image data of the respective drive target pixels to the respective signal electrodes, and simultaneously changes the orientations of the liquid crystal of each drive target pixel in accordance with the image data. For example, when the scan electrode R1 is selected, the orientations of the liquid crystal of the drive target pixels P11-P1n on the scan electrode R1 are changed in accordance with the pixel data of the respective drive target pixels. The voltage difference between the voltage applied to the scan electrode of the drive target pixel, and the voltage applied to the signal electrode and corresponding to the image data, is applied to the liquid crystal of the drive target pixel. Therefore, the orientation of the liquid crystal of the drive target pixel is changed in accordance with the image data. Every time the selected scan electrode is changed, the signal electrode drive IC 83 changes the orientations of the liquid crystal of the drive target pixels in accordance with the image data. This control is performed by the signal electrode drive controller 84 in parallel with the operation of reading image data from the image memory 85.

As described above, the liquid crystal of the drive target pixel is supplied with the voltage corresponding to the image data (tone data) of the drive target pixel. Therefore, in accordance with the image data of the drive target pixel, the liquid crystal of the drive target pixel can be set to the planar state, the focal conic state or the state where these states are mixed at a ratio corresponding to the display tone. Accordingly, gradation display corresponding to the image data can be performed.

The liquid crystal cells Cr and Cg can be driven in accordance with the image data in a similar manner, and thereby can perform the gradation display. By driving the three liquid crystal cells Cb, Cg and Cr in accordance with the image data, the full color display can be performed.

The other liquid crystal elements and layered type liquid crystal elements can be driven in the manner similar to the above.

[17] The substrate having the gas barrier layer, IZO transparent electrode and others formed thereon in the liquid crystal elements and layered type liquid crystal elements described above can be employed similarly in the organic elecro-luminescence element. Similarly the effects corresponding to the layers formed on the substrate can be also achieved in the organic elecro-luminescence element.

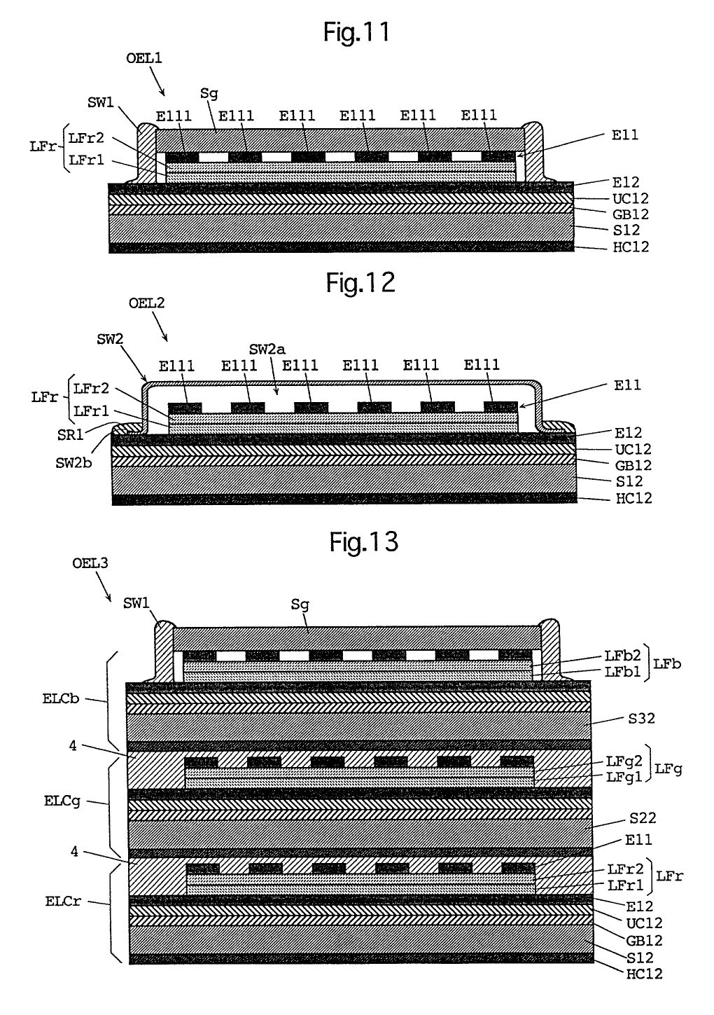

FIG. 11 is a schematic section view showing an example of the organic electro-luminescence element according to the present invention.

In the organic electro-luminescence element OEL1 shown in FIG. 11, an organic luminescent film LFr is formed on the resin substrate S12 on which the gas barrier layer and others are formed.

Stated more specifically, in the organic electro-luminescence element OEL1, the gas barrier layer GB12, undercoat layer UC12 and IZO transparent electrode E12 are formed successively in this order on the surface, near to the organic luminescent film LFr, of the substrate S12. In this example, the electrode E12 is used as a positive electrode. A hard coat layer HC12 is formed on the surface, remote from the organic luminescent film LFr, of the substrate S12.

The organic luminescent film LFr in this example has a hole injection/transport layer LFr1 and organic luminescent film LFr2 layered in this order. The organic luminescent film LFr emits light in red color by application of a voltage in this example.

The electrode E11 is formed on the organic luminescent film LFr. In this example, the electrode E11 is used as a negative electrode.

In the organic electro-luminescence element OEL1, the electrodes E11, E12 are formed of a plurality of belt-like electrode portions, which are parallel to each other with a predetermined space therebetween as in the liquid crystal element LCE1 of FIG. 1. These electrodes have a matrix structure.

In the organic electro-luminescence element OEL1, the organic luminescent film LFr in its entirety and electrodes E11, E12 substantially in their entirety are sealed against the outside air with a glass substrate Sg and the seal wall SW1 as described below.

The glass substrate Sg is arranged over the electrode E11, and covers over the whole organic luminescent film LFr and over the electrodes E11, E12 substantially in their entirety excluding the end portions thereof. The seal wall SW1 is arranged to extend from the peripheral portion of the glass substrate Sg toward the substrate S12. The seal wall SW1 is made of a UV-curing resin in this example.

Thereby the organic luminescent film LFr in its entirety and the electrodes E11, E12 substantially in their entirety are shielded against the outside air as mentioned above.

The end portions of electrodes E11, E12 are used to attach lead wires thereto, respectively, which are connected to a power source. After connecting the lead wires to the end portions of the electrodes, the end portions thereof may be covered with a resin or the like. In this way, the whole electrodes can be shielded against the outside air. Alternatively after attaching the lead wires to the end portions of the electrodes, the electrodes can be also shielded as a whole against the outside air by arranging the seal wall SW1 made of a resin so as to cover the whole end portions of the electrodes.

The desired characters, graphics and others can be displayed by performing matrix drive of organic electro-luminescence element OEL1 in the same manner as done for the layered type liquid crystal element LCE6 of FIG. 6.

In the organic electro-luminescence element OEL1, similar to the liquid crystal element LCE1 of FIG. 1, IZO is used as the material for electrodes so that a problem of cracks or the like occurring in the electrode is unlikely to arise during the production of the element, and the element can be produced in a higher yield.

The gas barrier layer GB12 is formed on the resin substrate S12 so that water and oxygen is prevented from passing from the side of the substrate S12 into the organic luminescent film LFr. The glass substrate Sg provided over the electrode E11 can hinder the penetration of water and oxygen and therefore can prevent the entry of water and oxygen from the side of the glass substrate Sg into the organic luminescent film LFr. The seal wall SW1 can preclude the penetration of water and oxygen. Consequently, in the organic electro-luminescence element OEL1, it is possible to suppress the deterioration of organic luminescent film LFr and the electrodes due to water and oxygen. Thereby, the organic electro-luminescence element OEL1 can stably achieve good luminescence for a long term.

Further it is possible to suppress separation of the electrode E12 from the substrate S12 by arrangement of the undercoat layer UC12 between the electrode E12 and the substrate S12.

The hard coat layer HC12 is formed on the outer side of the resin substrate S12 so that the surface of the substrate S12 is prevented from marring. Thereby it is possible to preclude the degradation of luminous quality and display quality which may occur due to the marring of the substrate surface. Consequently the organic electro-luminescence element OEL1 can perform good luminescence and good display for a long term.

[18] In the organic electro-luminescence element of the present invention, the methods and the structures for shielding the organic luminescent film and others against the outside air are not limited to those employed for the organic electro-luminescence element OEL1.

For example, an organic luminescent film and others may be shielded from the outside air as in the organic electro-luminescence element shown in FIG. 12.

In the organic electro-luminescence element OEL2 shown in FIG. 12, shielding is attained as described below by using a seal member SW2 and a seal resin SR1 in place of the glass substrate Sg and the seal wall SW1 employed in the organic electro-luminescence element OEL1 of FIG. 11. The seal member SW2 in this example is made of aluminum.

The seal member SW2 is in the shape of a hat. The seal member SW2 is arranged such that the organic luminescent film LFr and others are accommodated in a recess SW2a. The peripheral portion SW2b of the seal member SW2 is laid on the electrode E12. The seal resin SR1 is arranged to cover the contact portion between the seal member SW2 and the electrode E12. The seal resin SR1 covers the peripheral portion of the electrode which is not accommodated in the seal member recess SW2a.

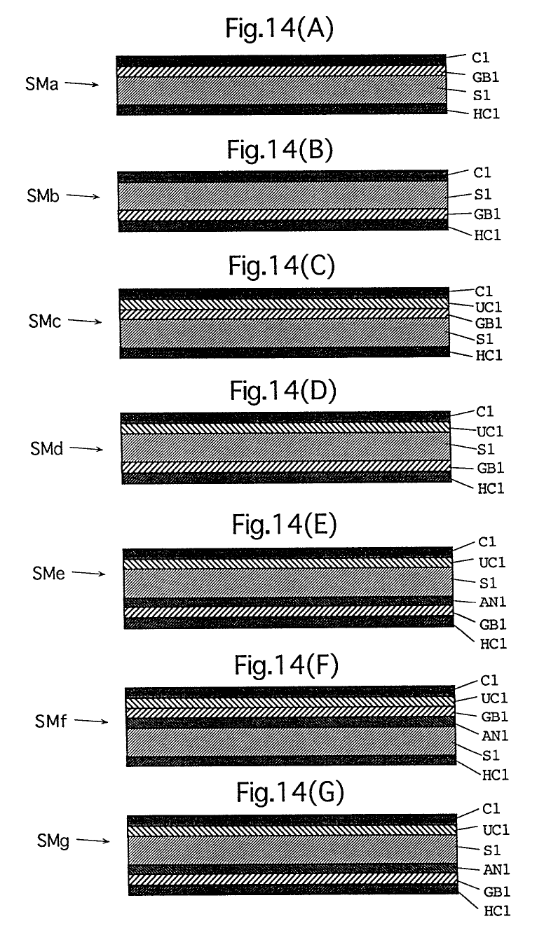

Thereby the organic luminescent film LFr and the electrodes can be prevented from deterioration due to water and oxygen in the organic electro-luminescence element OEL2.

[19] FIG. 13 is a schematic section view showing an example of the layered type organic electro-luminescence element (overlay type organic EL element) according to the present invention.

The layered type organic electro-luminescence element OEL3 (overlay type organic EL element) shown in FIG. 13 has three organic electro-luminescence cells ELCr, ELCg, ELCb layered together. Any of these organic electro-luminescence cells is structurally identical with the organic electro-luminescence element OEL1 of FIG. 11 from which the glass substrate Sg and the seal wall SW1 are removed.

The organic electro-luminescence cells ELCr, ELCg, ELCb have organic luminescent films LFr, LFg, LFb which emit light in red, green and blue colors, respectively. The organic luminescent films LFr, LFg, LFb are carried on the resin substrates S12, S22, S32, respectively.

The organic luminescent film LFr of the organic electro-luminescence cell ELCr has the hole injection/transport layer LFr1 and organic electro-luminescent layer LFr2 layered on each other. Likewise, the organic luminescent film LFg of the organic electro-luminescence cell ELCg has the hole injection/transport layer LFg1 and organic electro-luminescent layer LFg2 layered on each other. The organic luminescent film LFb of the organic electro-luminescence cell ELCb has the hole injection/transport layer LFb1 and organic electro-luminescent layer LFb2 layered on each other.

The gas barrier layer GB12, undercoat layer UC12 and IZO transparent electrode E12 are formed successively in this order on the substrate S12 of organic electro-luminescence cell ELCr on the side of organic luminescent film LFr, and the organic luminescent film LFr is formed on the electrode E12. The IZO transparent electrode E11 is further formed on the organic luminescent film LFr. The hard coat layer HC12 is formed on the other surface of the substrate S12. The same layers as on the substrate S12 are formed on the substrates S22, S32 of organic electro-luminescence cells ELCg, ELCb, respectively.

The adjoining organic electro-luminescence cells are adhered to each other with an adhesive 4. Thereby the organic luminescent films and the electrodes of the organic electro-luminescence cells ELCr and ELCg are shielded from the outside air.

The organic luminescent film LFb and the electrodes of the organic electro-luminescence cell ELCb are shielded from the outside air by the glass substrate Sg and seal wall SW1 as in the organic electro-luminescence element OLE1 of FIG. 11.

In the layered type organic electro-luminescence element (overlay type organic electro-luminescence element) OEL3, a color display can be performed by matrix drive of each organic electro-luminescence cell.

In the layered type organic electro-luminescence element (overlay type organic electro-luminescence element) OEL3, the effect corresponding to the layers formed on the resin substrate can be achieved.

In the layered type organic electro-luminescence element (overlay type organic electro-luminescence element) OEL3, similar to the organic electro-luminescence element OEL1 of FIG. 11, a problem of cracks or the like occurring in the electrode would be unlikely to arise because of IZO used as the material for electrodes, so that the element can be produced in a higher yield.

The organic luminescent film and electrodes can be prevented from deterioration due to water and oxygen because the gas barrier layer is formed on the resin substrate. The electrode can be precluded from separation from the substrate because the undercoat layer is provided between the electrode and the substrate.

The hard coat layer is arranged on the outer side of the resin substrate so that the substrate surface can be prevented from marring during, e.g., cells are layered on each other. Thereby the organic electro-luminescence element OEL3 can be prevented from lowering of luminous quality and display quality due to the marring of the substrate surface, ensuring the desired long-term light emission.

[20] Experiments were carried out to produce the liquid crystal elements, layered type liquid crystal elements and organic electro-luminescence elements according to the invention for investigation of characteristics thereof (Experimental Examples 1 to 10). The details of experiments will be given in the following description on the experimental examples. In each of the liquid crystal elements, the layered type liquid crystal elements and organic electro-luminescence elements in Experimental Examples 1 to 10, the substrate was made of resin, electrodes were made of IZO, and the gas barrier layer was provided on the resin substrate.

The layered type liquid crystal element free of the gas barrier layer was prepared for comparison with the layered type liquid crystal element of the invention and the former was also investigated as to the characteristics (Comparative Examples 1 to 3). Description will be given later as to Comparative Examples 1 to 3.

In any of Experimental Examples 1 to 10 and Comparative Examples 1 to 3, the number of broken electrodes (number of broken belt-like electrode portions) was counted among a plurality of belt-like electrode portions in the liquid crystal elements, layered type liquid crystal elements or organic electro-luminescence elements produced in Experimental Examples 1 to 10 and Comparative Examples 1 to 3. Investigations were conducted also as to the change of contrast before and after leaving the liquid crystal elements or layered type liquid crystal elements to stand in a high temperature/high humidity environment.

In any of Experimental Examples 1 to 10, the element was produced using any of substrate modules SMa to SMg to be described below in which the gas barrier layer and others are provided. First, description will be given on the substrate modules SMa to SMg in which the gas barrier layer and others are formed, followed by description on the experimental examples and comparative examples.

### Substrate Module SMa

FIG. 14(A) is a schematic section view of the substrate module SMa produced herein.

In the substrate module SMa, a polycarbonate (PC) film is used as a substrate S1. The substrate S1 is square and measures 10 cm by 10 cm and 140 μm in thickness. The gas barrier layer and others were formed on the substrate S1 as described below to provide the substrate module SMa.

First, a gas barrier layer GB1 of 100 nm thickness composed of SiOₓ (0<x≦2) and a transparent conductive film C1 of 150 nm thickness composed of IZO were formed successively in this order on one surface of the substrate S1. The IZO conductive film C1 was formed on the entire surface of the substrate S1. In a procedure to be taken later, the electrode was formed by patterning the IZO conductive film C1 into the predetermined configuration. The gas barrier layer GB1 and the IZO conductive film C1 were formed by a sputtering method. A sputtering target for forming the IZO film C1 was a sintered body made of a mixture of indium oxide and zinc oxide.

Then, a hard coat layer HC1 of 2 μm thickness composed of epoxy resin was formed on the other surface of the substrate S1. The hard coat layer HC1 was formed by coating the surface of the substrate with an epoxy resin and curing the coat.

In this way, the substrate module SMa was produced.

### Substrate Module SMb

FIG. 14(B)is a schematic section view of the substrate module SMb produced herein.

In the substrate module SMb, a polycarbonate (PC) film is used as a substrate S1. The substrate S1 is square and measures 10 cm by 10 cm and 100 μm in thickness. A gas barrier layer and others were formed on the substrate S1 as described below to provide the substrate module SMb.

First, a gas barrier layer GB1 of 50 nm thickness composed of SiOₓ (0<x≦2) and a hard coat layer HC1 of 2 μm thickness composed of epoxy resin were formed successively in this order on one surface of the substrate S1. The gas barrier layer GB1 was formed by a sputtering method. The hard coat layer HC1 was formed by coating the surface of the substrate with an epoxy resin and curing the coat.

Then, a transparent conductive film C1 of 100 nm thickness composed of IZO was formed on the other surface of the substrate S1. The IZO conductive film C1 was formed on the entire surface of the substrate S1 by a sputtering method. A sputtering target for forming the IZO film C1 was a sintered body made of a mixture of indium oxide and zinc oxide.

In this way, the substrate module SMb was produced.

### Substrate Module SMc

FIG. 14(C) is a schematic section view of the substrate module SMc produced herein.

In the substrate module SMc, a substrate S1 is a polycarbonate (PC) film. The substrate S1 is square and measures 10 cm by 10 cm and 150 μm in thickness. A gas barrier layer and others were formed on the substrate S1 as described below to provide the substrate module SMc.

First, a gas barrier layer GB1 of 100 nm thickness composed of SiOₓ (0<x≦2), an undercoat layer UC1 of 3 μm thickness composed of urethane resin, and a transparent conductive film C1 of 120 nm thickness composed of IZO were formed successively in this order on one surface of the substrate S1. The IZO conductive film C1 was formed on the entire surface of the substrate S1. The gas barrier layer GB1 and the IZO conductive film C1 were formed by a sputtering method. A sputtering target for forming the IZO film C1 was a sintered body made of a mixture of halogen-doped indium oxide and zinc oxide.

Then, a hard coat layer HC1 of 2 μm thickness composed of epoxy resin was formed on the other surface of the substrate S1. The hard coat layer HC1 was formed by coating the surface of the substrate with an epoxy resin and curing the coat.

In this way, the substrate module SMc was produced.

### Substrate Module SMd

FIG. 14(D) is a schematic section view of the substrate module SMd produced herein.

In the substrate module SMd, a substrate S1 is a polycarbonate (PC) film. The substrate S1 is square and measures 10 cm by 10 cm and 100 μm in thickness. A gas barrier layer and others were formed on the substrate S1 as described below to provide the substrate module SMd.

First, a gas barrier layer GB1 of 80 nm thickness composed of SiOₓ (0<x≦2) and a hard coat layer HC1 of 2 μm thickness composed of epoxy resin were formed successively in this order on one surface of the substrate S1. The gas barrier layer GB1 was formed by a sputtering method. The hard coat layer HC1 was formed by coating the surface of the substrate with an epoxy resin and curing the coat.

Then, an undercoat layer UC1 of 3 μm thickness composed of urethane resin and a transparent conductive film C1 of 140 nm thickness composed of IZO were formed successively in this order on the other surface of the substrate S1. The IZO conductive film C1 was formed on the entire surface of the substrate S1 by a sputtering method. A sputtering target for forming the IZO conductive film C1 is a sintered body made of a mixture of indium oxide and zinc oxide.

In this way, the substrate module SMd was produced.

### Substrate Module SMe

FIG. 14(E) is a schematic section view of the substrate module SMe produced herein.

In the substrate module SMe, a substrate S1 is a polycarbonate (PC) film. The substrate S1 is square and measures 10 cm by 10 cm and 200 μm in thickness. A gas barrier layer and others were formed on the substrate S1 as described below to form the substrate module SMe.

First, an anchor layer of 2 μm thickness composed of urethane resin, a gas barrier layer GB1 of 150 nm thickness composed of SiOₓ (0<x≦2) and a hard coat layer HC1 of 2 μm thickness composed of epoxy resin were formed successively in this order on one surface of the substrate S. The gas barrier layer GB1 was formed by a sputtering method. The hard coat layer HC1 was formed by coating the surface of the substrate with an epoxy resin and curing the coat.

Then, an undercoat layer of 3 μm thickness composed of urethane resin and a transparent conductive film C1 of 150 nm thickness composed of IZO were formed successively in this order on the other surface of the substrate S1. The IZO transparent conductive film C1 was formed on the entire surface of the substrate S by a sputtering method. A sputtering target for forming the IZO film C1 was a sintered body made of a mixture of indium oxide and zinc oxide.

In this way, the substrate module SMe was produced.

### Substrate Module SMf

FIG. 14(F) is a schematic section view of the substrate module SMf produced herein.

The substrate module SMf has a polycarbonate (PC) film as a substrate S1. The substrate S1 is square and measures 10 cm by 10 cm and 130 μm in thickness. A gas barrier layer and others were formed on the substrate S1 as described below to provide the substrate module SMf.

First, an anchor layer of 2 μm thickness composed of urethane resin, a gas barrier layer GB1 of 30 nm thickness composed of SiOₓ (0<x≦2), an undercoat layer UC1 of 1 μm thickness composed of urethane resin and a transparent conductive film C1 of 180 nm thickness composed of IZO were formed successively in this order on one surface of the substrate S1. The IZO conductive film C1 was formed on the entire surface of the substrate S1. The IZO conductive film C1 and gas barrier layer GB1 were formed by a sputtering method. The sputtering target for forming the IZO conductive film C1 was a sintered body made of a mixture of halogen-doped indium oxide and zinc oxide.

Then, a hard coat layer HC1 of 3 μm thickness composed of UV-curing acrylic resin was formed on the other surface of the substrate S1. The hard coat layer was formed by applying a UV-curing acrylic resin to the substrate surface and curing the resin by UV irradiation.

In this way, the substrate module SMf was produced.

### Substrate Module SMg

FIG. 14(G) is a schematic section view of the substrate module SMg produced herein.

The substrate module SMg has a polycarbonate (PC) film as a substrate S1. The substrate S1 is square and measures 10 cm by 10 cm and 120 μm in thickness. A gas barrier layer and others were formed on the substrate S1 as described below to provide the substrate module SMg.

First, an anchor layer AN1 of 1 μm thickness composed of acrylic resin, a gas barrier layer GB1 of 100 nm thickness composed of Al₂O₃, and a hard coat layer HC1 of 2 μm thickness composed of epoxy resin were formed successively in this order on one surface of the substrate S1. The gas barrier layer GB1 was formed by a sputtering method. The hard coat layer HC1 was formed by coating the substrate surface with an epoxy resin and curing the coat.

Then, an undercoat layer UC1 of 3 μm thickness composed of urethane resin and a transparent conductive film C1 of 130 nm thickness composed of IZO were formed successively in this order on the other surface of the substrate S1. The IZO conductive film C1 was formed on the entire surface of the substrate S1 by a sputtering method. A sputtering target for forming the IZO conductive film C1 is a sintered body made of a mixture of halogen-doped indium oxide and zinc oxide.

In this way, the substrate module SMfg was produced.

Experimental Examples 1 to 10 and Comparative Examples 1 to 3 will be described below.

### [20-1] Experimental Example 1

In Experimental Example 1, a liquid crystal element was prepared as described below using two substrate modules SMa (first and second substrate modules). Hereinafter the substrate of the first substrate module will be referred to as “first substrate” and the substrate of the second substrate module will be referred to as “second substrate”.

A transparent electrode, having a plurality of belt-like electrode portions which are parallel to each other with a predetermined space therebetween, was prepared by patterning the IZO conductive film on the first substrate into belt-like forms (parallel stripes). Each of the belt-like electrode portions was 180 μm wide and was spaced away by 20 μm from the adjoining belt-like electrode portion. On the electrode formed over the first substrate, an orientation film of 800 Å in thickness was formed with a polyimide-containing material for orientation films (trade name “AL4552”, produced by JSR Corp.).

A transparent electrode having a plurality of belt-like electrode portions was produced by patterning the IZO conductive film on the second substrate into belt-like forms. Each of the belt-like electrode portions was 180 μm wide and spaced away by 20 μm from the adjacent belt-like electrode portion. An insulating film of 2000 Å in thickness and an orientation film of 800 Å in thickness were formed successively in this order over the electrode on the second substrate. The insulating film was made of a polyimide-containing material for insulating films (trade name HIM 3000, produced by Hitachi Chemical Co., Ltd.). The orientation film was formed of a polyimide-containing material for orientation films (trade name AL4552, produced by JSR Corp.).

Spacers of 9 μm in diameter (product of Sekisui Fine Chemical Co., Ltd.) were dispersed over the orientation film on the first substrate. Thus, the liquid crystal element of Experimental Example 1 had a liquid crystal layer of 9 μm in thickness.

Then, a seal material (trade name “XN21S” produced by Mitsui Chemicals, Inc.) was applied by a screen printing method onto the peripheral portion of the first substrate so that a frame-like wall of a predetermined height was formed. The wall made of the seal material will be used as the seal wall for preventing leakage of the liquid crystal in a later stage.

Thereafter, the liquid crystal composition LCr in an amount, which corresponded to the area of the region surrounded by the seal wall on the first substrate and the height of this seal wall, was applied onto the region surrounded by the seal wall on the first substrate. The liquid crystal composition LCr thus applied was as follows.

The liquid crystal composition LCr was a chiral nematic liquid crystal composition formed by adding a chiral material S-811 (produced by Merck & Co.) in an amount of 17% by weight to a nematic liquid crystal composition (having a refractive index anisotropy An of 0.187 and dielectric anisotropy Δε of 4.47). The liquid crystal composition LCr had the selective reflection wavelengths of about 680 nm (red region), and exhibited the cholesteric phase at room temperature.

Then, the first and second substrates were fixed together with the liquid crystal composition LCr therebetween in such manner that the belt-like electrode portions on the first substrate cross those on the second substrate at a right angle. The liquid crystal cell thus prepared by fixing the substrates was heated to 150° C. for one hour so that the seal material was melted to adhere onto the first and second substrates and was cooled to room temperature. Thereafter, a black light absorbing layer was formed on the outer side of the hard coat layer on the second substrate to be arranged on the side remote from the observation side.

In this way, a liquid crystal element was produced.

The number of broken belt-like electrode portions was counted among those formed on the first and second substrates in the liquid crystal element thus produced. As a result, only one broken belt-like electrode portion was detected in a total of 500 belt-like electrode portions in the liquid crystal element of Experimental Example 1.

The display characteristics of the liquid crystal element thus prepared were measured by the spectrocolorimeter CM-3700d (produced by Minolta Co., Ltd.). Y-value (red) was measured when the liquid crystal layer was in the selective reflection state (planar state), and therefore the red display was performed. Also, Y-value (black) was measured when the liquid crystal layer was in the transparent state (focal conic state) and therefore the black display was performed. When the liquid crystal layer was in the transparent state, the color (black) of the light absorbing film arranged on the outer side of the second substrate was displayed. Y-value is a luminous reflectance. The contrast [=(Y-value (red))/(Y-value (black))] was calculated from the Y-value (red) and the Y-value (black). The larger value in contrast represents better contrast.

The liquid crystal element of Experimental Example 1 exhibited a good contrast of 8.1. The liquid crystal element of Experimental Example 1 was good in both the red and black display characteristics, and the contrast was high.

After the liquid crystal element was left to stand for 100 hours in a high temperature/high humidity environment (70° C./80% RH), the display characteristics of the liquid crystal element were measured again. The liquid crystal element of Experimental Example 1 showed no deterioration in display characteristics, that is, no reduction of contrast.

In the liquid crystal element of Experimental Example 1, the drive voltages for setting the liquid crystal layer to the selective reflection state and the transparent state were equal to 85 V and 55 V, respectively.

### [20-2] Experimental Example 2

In Experimental Example 2, a layered type liquid crystal element, in which three liquid crystal cells for red, green and blue displays were layered in this order, was produced as follows.

First, a liquid crystal cell for red display including a liquid crystal layer for red display, a liquid crystal cell for green display including a liquid crystal layer for green display, and a liquid crystal cell for blue display including a liquid crystal layer for blue display were each produced in the following manners.

### LIQUID CRYSTAL CELL FOR RED DISPLAY

### (LIQUID CRYSTAL CELL TO BE ARRANGED IN A POSITION REMOTEST FROM THE OBSERVATION SIDE)

In Experimental Example 2, the liquid crystal cell for red display was produced using two substrate modules SMa (first and second substrate modules). Hereinafter the substrate of the first substrate module will be referred to as “first substrate” and the substrate of the second substrate module will be referred to as “second substrate”.

First, a transparent electrode, having a plurality of belt-like electrode portions which are parallel to each other with a predetermined space therebetween, was prepared by patterning the IZO conductive film on the first substrate into belt-like forms (parallel stripes). Each of the belt-like electrode portions was 150 μm wide and was spaced away by 15 μm from the neighboring electrode portion. Over the electrode on the first substrate, an orientation film of 800 Å in thickness was formed with a polyimide-containing material for orientation films (trade name “AL4552” produced by JSR Corp.).

A transparent electrode having a plurality of belt-like electrode portions was produced by patterning the IZO conductive film on the second substrate into belt-like forms. Each of the belt-like electrode portions was 150 μm wide and was spaced away by 15 μm from the adjacent electrode portion. An insulating film of 2000 Å in thickness and an orientation film of 800 Å in thickness were formed in this order over the electrode on the second substrate. The insulating film was made of a polyimide-containing material for insulating films (trade name “HIM 3000” produced by Hitachi Chemical Co., Ltd.). The orientation film was formed with a polyimide-containing material for orientation films (trade name “AL4552” produced by JSR Corp.).

Spacers of 9 μm in diameter (product of Sekisui Fine Chemical Co., Ltd.) were dispersed over the orientation film on the first substrate. Thus, the liquid crystal cell for red display in Experimental Example 2 had a liquid crystal layer of 9 μm in thickness.

Then, a seal material (trade name “XN21S” produced by Mitsui Chemicals, Inc.) was applied by a screen printing method onto the peripheral portion of the first substrate so that a frame-like wall of a predetermined height was formed. The wall made of the seal material will be used as the seal wall for preventing leakage of the liquid crystal in a later stage.

Thereafter, a liquid crystal composition LCr was applied onto the region surrounded by the seal wall on the first substrate. The amount of the liquid crystal composition LCr thus applied corresponded to the area of the region surrounded by the seal wall on the first substrate and the height of this seal wall. The liquid crystal composition LCr was as follows.

The liquid crystal composition LCr was a chiral nematic liquid crystal composition formed by adding a chiral material S-811 (produced by Merck & Co.) in an amount of 17% by weight to a nematic liquid crystal composition (having a refractive index anisotropy An of 0.187 and dielectric anisotropy Δε of 4.47). The liquid crystal composition LCr had the selective reflection wavelengths of about 680 nm (red region), and exhibited the cholesteric phase at room temperature.

Then, the first and second substrates were fixed together with the liquid crystal composition LCr therebetween in such manner that the belt-like electrode portions on the first substrate cross those on the second substrate at a right angle. The liquid crystal cell thus prepared by fixing the substrates was heated to 150° C. for one hour so that the seal material was melted to adhere to the first and second substrates and was cooled to room temperature.

In this way, the liquid crystal cell for red display was produced.

### LIQUID CRYSTAL CELL FOR GREEN DISPLAY

### (LIQUID CRYSTAL CELL TO BE ARRANGED IN AN MIDDLE POSITION)

The liquid crystal cell for green display was prepared in the same manner as done for the liquid crystal cell for red display except the following.

In the liquid crystal cell for green display, spacers of 7 μm in diameter were used instead of spacers of 9 μm in diameter. Thus, the liquid crystal cell for green display had a liquid crystal layer with a thickness of 7 μm.

In the liquid crystal cell for green display, a liquid crystal composition LCg was used as the liquid crystal held between the two substrates. The liquid crystal composition LCg was a chiral nematic liquid crystal composition formed by adding the chiral material S-811 (produced by Merck & Co.) in an amount of 22% by weight to a nematic liquid crystal composition (having refractive index anisotropy An of 0.177 and dielectric anisotropy Δε of 5.33). The liquid crystal composition LCg had the selective reflection wavelengths of about 560 nm (green region), and exhibited the cholesteric phase at room temperature.

### LIQUID CRYSTAL CELL FOR BLUE DISPLAY

### (LIQUID CRYSTAL CELL TO BE ARRANGED AT THE POSITION NEAREST TO THE OBSERVATION SIDE)

The liquid crystal cell for blue display was prepared in the same manner as done for the liquid crystal cell for red display except the following.

In the liquid crystal cell for blue display, spacers of 5 μm in diameter were used instead of spacers of 9 μm in diameter. Thus, the liquid crystal cell for blue display had a liquid crystal layer with a thickness of 5 μm.

In the liquid crystal cell for blue display, the following liquid crystal composition LCb was used as the liquid crystal held between the two substrates. The liquid crystal composition LCb was a chiral nematic liquid crystal composition formed by adding the chiral material S-811 (produced by Merck & Co.) in an amount of 26% by weight to a nematic liquid crystal composition (Δn: 0.20 and Δε: 6.25). The liquid crystal composition LCb had the selective reflection wavelengths of about 480 nm (blue region), and exhibited the cholesteric phase at room temperature.

Then, the liquid crystal cells for red, green and blue displays thus prepared were adhered together in this order.

Then, the black light absorbing film was formed on the outer side of the liquid crystal cell for red display, which was to be located remotest from the observation side.

In these manners, the layered type liquid crystal element was prepared.

In the layered type liquid crystal element of Experimental Example 2, only three belt-like electrode portions were broken in a total of 606 belt-like electrode portions.

The display characteristics of the layered type liquid crystal element thus prepared were measured by the spectrocolorimeter CM-3700d (produced by Minolta Co., Ltd.). Y-value (white) was measured when each of the liquid crystal layers in the liquid crystal cells was in the selective reflection state (planar state), and therefore the white display was performed. Also, Y-value (black) was measured when each of the liquid crystal layers in the liquid crystal cells was in the transparent state (focal conic state) and therefore the black display was performed. When each of the liquid crystal layers in the liquid crystal cells was transparent, the color (black) of the light absorbing film arranged on the outer side of the liquid crystal cell for red display was displayed. The contrast [=(Y-value (white))/(Y-value (black))] was calculated from the Y-value (white) and the Y-value (black).

The layered type liquid crystal element of Experimental Example 2 exhibited a good contrast of 6.0. The layered type liquid crystal element of Experimental Example 2 was good in both the white and black display characteristics, and the contrast was high.

After the layered type liquid crystal element of Experimental Example 2 was left to stand for 100 hours in a high temperature/high humidity environment (70° C./80% RH), similar to Experimental Example 1, the display characteristics of the layered type liquid crystal element were measured again. The layered type liquid crystal element of Experimental Example 2 did not exhibit deteriorated display characteristics.

In the layered type liquid crystal element of Experimental Example 2, the drive voltages for setting the liquid crystal layer of liquid crystal cell for red display to the selective reflection state and the transparent state were equal to 85 V and 55 V, respectively. The drive voltages for setting the liquid crystal layer of liquid crystal cell for green display to the selective reflection state and the transparent state were equal to 90 V and 60 V, respectively. The drive voltages for setting the liquid crystal layer of liquid crystal cell for blue display to the selective reflection state and the transparent state were equal to 95 V and 65 V, respectively.

### [20-3] Experimental Example 3

In Experimental Example 3, a layered type liquid crystal element, in which three liquid crystal cells for red, green and blue displays were layered in this order, was produced as described below.

The layered type liquid crystal element of Experimental Example 3 was produced in the same manner as in Experimental Example 2 except the following.

In Experimental Example 3, each liquid crystal cell was prepared using the substrate module SMb instead of the substrate module SMa. Using the substrate module SMb, the layered type liquid crystal element was prepared by conducting the same step of producing the electrode by patterning the IZO film on the substrate and the same subsequent step as in Experimental Example 2. In Experimental Example 3, each of the belt-like electrode portions was 150 μm wide and was spaced away by 15 μm from the neighboring electrode portion as in Experimental Example 2.

In the layered type liquid crystal element prepared in Experimental Example 3, only two belt-like electrode portions were broken in a total of 606 belt-like electrode portions.

The layered type liquid crystal element of Experimental Example 3 was investigated as to the contrast in the same manner as in Experimental Example 2 and was found to exhibit a good contrast of 6.6. The layered type liquid crystal element of Experimental Example 3 was good in both the white and black display characteristics, and the contrast was high.

After the layered type liquid crystal element of Experimental Example 3 was left to stand for 100 hours in a high temperature/high humidity environment (70° C./80% RH), the layered type liquid crystal element thereof was not deteriorated in display characteristics.

In the layered type liquid crystal element of Experimental Example 3, the drive voltages for setting the liquid crystal layer of liquid crystal cell for red display to the selective reflection state and the transparent state were equal to 85 V and 55 V, respectively. The drive voltages for setting the liquid crystal layer of liquid crystal cell for green display to the selective reflection state and the transparent state were equal to 90 V and 60 V, respectively. The drive voltages for setting the liquid crystal layer of liquid crystal cell for blue display to the selective reflection state and the transparent state were equal to 95 V and 65 V, respectively.

### [20-4] Experimental Example 4

In Experimental Example 4, a layered type liquid crystal element, in which three liquid crystal cells for red, green and blue displays were layered in this order, was produced as described below.

The layered type liquid crystal element of Experimental Example 4 was produced in the same manner as in Experimental Example 2 except the following.

In Experimental Example 4, each liquid crystal cell was prepared using the substrate module SMc instead of the substrate module SMa. Using the substrate module SMc, the layered type liquid crystal element was prepared by carrying out the same step of patterning the IZO film on the substrate to form an electrode and the same subsequent step as in Experimental Example 2. In Experimental Example 4, each of the belt-like electrode portions was 150 μm wide and was spaced away by 15 μm from the neighboring electrode portion as in Experimental Example 2.

In the layered type liquid crystal element prepared in Experimental Example 4, no break was detected in a total of 606 belt-like electrode portions.

The layered type liquid crystal element of Experimental Example 4 was investigated as to the contrast in the same manner as in Experimental Example 2.

The layered type liquid crystal element of Experimental Example 4 exhibited a good contrast of 6.3. The layered type liquid crystal element of Experimental Example 4 was good in both the white and black display characteristics, and the contrast was high.

Even after standing for 100 hours in a high temperature/high humidity environment (70° C./80% RH), the layered type liquid crystal element of Experimental Example 4 was not deteriorated in display characteristics.

In the layered type liquid crystal element of Experimental Example 4, the drive voltages for setting the liquid crystal layer of liquid crystal cell for red display to the selective reflection state and the transparent state were equal to 85 V and 55 V, respectively. The drive voltages for setting the liquid crystal layer of liquid crystal cell for green display to the selective reflection state and the transparent state were equal to 90 V and 60 V, respectively. The drive voltages for setting the liquid crystal layer of liquid crystal cell for blue display to the selective reflection state and the transparent state were equal to 95 V and 65 V, respectively.

### [20-5] Experimental Example 5

In Experimental Example 5, a layered type liquid crystal element, in which three liquid crystal cells for red, green and blue displays were layered in this order, was produced as described below.

The layered type liquid crystal element of Experimental Example 5 was produced in the same manner as in Experimental Example 2 except the following.

In Experimental Example 5, each liquid crystal cell was prepared using the substrate module SMd instead of the substrate module SMa. Using the substrate module SMd, the layered type liquid crystal element was prepared by carrying out the same step of patterning the IZO film on the substrate to form an electrode and the same subsequent step as in Experimental Example 2. In Experimental Example 5, each of the belt-like electrode portions was 150 μm wide and was spaced away by 15 μm from the neighboring electrode portion as in Experimental Example 2.

In the layered type liquid crystal element prepared in Experimental Example 5, no break was detected in a total of 606 belt-like electrode portions.

The layered type liquid crystal element of Experimental Example 5 was investigated as to the contrast in the same manner as in Experimental Example 2. The layered type liquid crystal element of Experimental Example 5 exhibited a good contrast of 6.5. The layered type liquid crystal element of Experimental Example 5 was good in both the white and black display characteristics, and the contrast was high.

Even after standing for 100 hours in a high temperature/high humidity environment (70° C./80% RH), the layered type liquid crystal element of Experimental Example 5 showed no deterioration in display characteristics.

In the layered type liquid crystal element of Experimental Example 5, the drive voltages for setting the liquid crystal layer of liquid crystal cell for red display to the selective reflection state and the transparent state were equal to 85 V and 55 V, respectively. The drive voltages for setting the liquid crystal layer of liquid crystal cell for green display to the selective reflection state and the transparent state were equal to 90 V and 60 V, respectively. The drive voltages for setting the liquid crystal layer of liquid crystal cell for blue display to the selective reflection state and the transparent state were equal to 95 V and 65 V, respectively.

### [20-6] Experimental Example 6

In Experimental Example 6, a layered type liquid crystal element, in which three liquid crystal cells for red, green and blue displays were layered in this order, was produced as described below.

The layered type liquid crystal element of Experimental Example 6 was produced in the same manner as in Experimental Example 2 except the following.

In Experimental Example 6, each liquid crystal cell was prepared using the substrate module SMe instead of the substrate module SMa. Using the substrate module SMe, the layered type liquid crystal element was prepared by carrying out the same step of patterning the IZO film on the substrate to form an electrode and the same subsequent step as in Experimental Example 2. In Experimental Example 6, each of the belt-like electrode portions was 150 μm wide and was spaced away by 15 μm from the neighboring electrode portion as in Experimental Example 2.

In the layered type liquid crystal element prepared in Experimental Example 6, no break was detected in a total of 606 belt-like electrode portions.

The layered type liquid crystal element of Experimental Example 6 was investigated as to the contrast in the same manner as in Experimental Example 2. The layered type liquid crystal element of Experimental Example 6 exhibited a good contrast of 5.8. The layered type liquid crystal element of Experimental Example 6 was good in both the white and black display characteristics, and the contrast was high.

Even after standing for 100 hours in a high temperature/high humidity environment (70° C./80% RH), the layered type liquid crystal element of Experimental Example 6 showed no deterioration in display characteristics.

In the layered type liquid crystal element of Experimental Example 6, the drive voltages for setting the liquid crystal layer of liquid crystal cell for red display to the selective reflection state and the transparent state were equal to 85 V and 55 V, respectively. The drive voltages for setting the liquid crystal layer of liquid crystal cell for green display to the selective reflection state and the transparent state were equal to 90 V and 60 V, respectively. The drive voltages for setting the liquid crystal layer of liquid crystal cell for blue display to the selective reflection state and the transparent state were equal to 95 V and 65 V, respectively.

### [20-7] Experimental Example 7

In Experimental Example 7, a layered type liquid crystal element, in which three liquid crystal cells for red, green and blue displays were layered in this order, was produced as described below.

The layered type liquid crystal element of Experimental Example 7 was produced in the same manner as in Experimental Example 2 except the following.

In Experimental Example 7, each liquid crystal cell was prepared using the substrate module SMf instead of the substrate module SMa. Using the substrate module SMf, the layered type liquid crystal element was prepared by carrying out the same step of patterning the IZO film on the substrate to form an electrode and the same subsequent step as in Experimental Example 2. In Experimental Example 7, each of the belt-like electrode portions was 150 μm wide and was spaced away by 15 μm from the neighboring electrode portion as in Experimental Example 2.

In the layered type liquid crystal element prepared in Experimental Example 7, no break was detected in a total of 606 belt-like electrode portions.

The layered type liquid crystal element of Experimental Example 7 was investigated as to the contrast in the same manner as in Experimental Example 2. The layered type liquid crystal element of Experimental Example 7 exhibited a good contrast of 6.4. The layered type liquid crystal element of Experimental Example 7 was good in both the white and black display characteristics, and the contrast was high.

Even after standing for 100 hours in a high temperature/high humidity environment (70° C./80% RH), the layered type liquid crystal element of Experimental Example 7 showed no deterioration in display characteristics.

In the layered type liquid crystal element of Experimental Example 7, the drive voltages for setting the liquid crystal layer of liquid crystal cell for red display to the selective reflection state and the transparent state were equal to 85 V and 55 V, respectively. The drive voltages for setting the liquid crystal layer of liquid crystal cell for green display to the selective reflection state and the transparent state were equal to 90 V and 60 V, respectively. The drive voltages for setting the liquid crystal layer of liquid crystal cell for blue display to the selective reflection state and the transparent state were equal to 95 V and 65 V, respectively.

### [20-8] Experimental Example 8

In Experimental Example 8, a layered type liquid crystal element, in which three liquid crystal cells for red, green and blue displays were layered in this order, was produced as described below.

The layered type liquid crystal element of Experimental Example 8 was produced in the same manner as in Experimental Example 2 except the following.

In Experimental Example 8, each liquid crystal cell was prepared using the substrate module SMg instead of the substrate module SMa. Using the substrate module SMg, the layered type liquid crystal element was prepared by carrying out the same step of patterning the IZO film on the substrate to form an electrode and the same subsequent step as in Experimental Example 2. In Experimental Example 8, each of the belt-like electrode portions was 150 μm wide and was spaced away by 15 μm from the neighboring electrode portion as in Experimental Example 2.

In the layered type liquid crystal element prepared in Experimental Example 8, no break was detected in a total of 606 belt-like electrode portions.

The layered type liquid crystal element of Experimental Example 8 was investigated as to the contrast in the same manner as in Experimental Example 2. The layered type liquid crystal element of Experimental Example 8 exhibited a good contrast of 6.2. The layered type liquid crystal element of Experimental Example 8 was good in both the white and black display characteristics, and the contrast was high.

Even after standing for 100 hours in a high temperature/high humidity environment (70° C./80% RH), the layered type liquid crystal element of Experimental Example 8 showed no deterioration in display characteristics.

In the layered type liquid crystal element of Experimental Example 8, the drive voltages for setting the liquid crystal layer of liquid crystal cell for red display to the selective reflection state and the transparent state were equal to 85 V and 55 V, respectively. The drive voltages for setting the liquid crystal layer of liquid crystal cell for green display to the selective reflection state and the transparent state were equal to 90 V and 60 V, respectively. The drive voltages for setting the liquid crystal layer of liquid crystal cell for blue display to the selective reflection state and the transparent state were equal to 95 V and 65 V, respectively.

### [20-9] Experimental Example 9

In Experimental Example 9, an organic electro-luminescence element having the same structure as the organic electro-luminescence element OEL1 of FIG. 11 was prepared as described below using the substrate module SMc.

An electrode having a plurality of belt-like electrode portions was produced by patterning the IZO conductive film of the substrate module SMc in the same manner as in Experimental Example 1. In Experimental Example 9, each of the belt-like electrode portions was 180 μm wide and was spaced away by 20 μm from the adjacent electrode portion as in Experimental Example 1. In the organic electro-luminescence element of Experimental Example 9, the IZO electrode thus prepared was used as a positive electrode.

Then, the IZO electrode was subjected to ultrasonic cleaning in an aqueous solution containing a surfactant for 15 minutes. Thereafter the IZO electrode was irradiated with light emitted from an excimer lamp for 5 minutes and exposed to oxygen plasma for 10 minutes for further cleaning.

The substrate having the IZO electrode thus cleaned was set to a holder of a film-forming device, and a hole injection/transport layer of 60 nm in thickness was formed on the IZO electrode under a vacuum of 1.0×10⁻⁵ Torr. The hole injection/transport layer was formed by a resistance heating method using N,N′-diphenyl-N,N′-bis(3-methylphenyl)-1,1′-diphenyl-4,4′-diamine at a vapor deposition rate of 1 Å/sec.

Next, a luminescent layer of 60 nm in thickness was formed on the hole injection/transport layer by vapor deposition using tris(8-hydroxyquinoline)aluminum complex at a vapor deposition rate of 1 Å/sec.

Subsequently, a negative electrode of about 200 nm in thickness was formed on the luminescent layer as described below. The negative electrode was produced by co-deposition according to a resistance heating method using magnesium (Mg) and silver (Ag) as a deposition source at a Mg:Ag ratio of vapor deposition rate of 10:1.

Thereafter, the organic luminescent film and others (luminescent layer and hole injection/transport layer) were accommodated in a globe box filled with nitrogen, and were sealed against the outside air using the cleaned glass substrate and UV-curing resin similar to the organic electro-luminescence element OEL1 of FIG. 11. The UV-curing resin forming the seal wall was cured by UV irradiation for 200 seconds.

Thereby the organic electro-luminescence element was produced.

In the organic electro-luminescence element prepared in Experimental Example 9, no break was detected in a total of 500 belt-like electrode portions.

The organic electro-luminescence element of Experimental Example 9 was driven under constant current conditions at an initial luminous intensity of 200 cd/m² to observe the luminous state and change of luminous intensity.

The result was that in the organic electro-luminescence element of Experimental Example 9, deterioration such as a dark spot was not detected even after a time lapse of 100 hours from the start of driving. The luminous intensity half-value period (a period during which the luminous intensity is reduced to a half the initial luminous intensity) was 500 hours. Deterioration such as oxidation of the negative electrode was not found.

### [20-10] Experimental Example 10

In Experimental Example 10, an organic electro-luminescence element was prepared in the same manner as in Experimental Example 9 except the following.

In Experimental Example 10, sealing was formed with a seal member made of aluminum and a UV-curing resin, as in the organic electro-luminescence element OEL2 of FIG. 12, instead of using the glass substrate and the UV-curing resin.

In the organic electro-luminescence element prepared in Experimental Example 10, no break was detected in a total of 500 belt-like electrode portions.

The organic electro-luminescence element of Experimental Example 10 was driven in the same manner as in Experimental Example 9 to observe the luminous state and the change of luminous intensity.

As a result, the organic electro-luminescence element of Experimental Example 10 did not show deterioration such as a dark spot even after a time lapse of 100 hours from the start of driving. The luminous intensity half-value period was 500 hours. The degradation such as oxidation of negative electrode was not found.

### [20-11] Comparative Example 1

In Comparative Example 1, a layered type liquid crystal element, in which three liquid crystal cells for red, green and blue displays were layered in this order, was produced as described below.

The layered type liquid crystal element of Comparative Example 1 was produced in the same manner as in Experimental Example 2 except the following.

In Comparative Example 1, each liquid crystal cell of the layered type liquid crystal element was prepared using a substrate module SMh instead of the substrate module SMa.

The substrate module SMh has a film substrate made of polycarbonate (PC). The substrate is square and measures 10 cm by 10 cm and 140 μm in thickness. Only a 150 nm-thick transparent conductive film made of ITO was formed on the substrate of the substrate module SMh. The ITO film was formed by a sputtering method.

Using the substrate module SMh, the layered type liquid crystal element was prepared by carrying out the similar step of patterning the ITO film on the substrate to form an electrode and the same subsequent step as in Experimental Example 2. In Comparative Example 1, each of the belt-like electrode portions was 180 μm wide and was spaced away by 20 μm from the neighboring electrode portion.

In the layered type liquid crystal element prepared in Comparative Example 1, twenty belt-like electrode portions were broken in a total of 500 belt-like electrode portions.

The layered type liquid crystal element of Comparative Example 1 was investigated as to the contrast in the same manner as in Experimental Example 2. The layered type liquid crystal element of Comparative Example 1 exhibited an initial contrast of 5.8. However, after standing for 100 hours in a high temperature/high humidity environment (70° C./80% RH), the layered type liquid crystal element of Comparative Example 1 was lowered to 3.9 in contrast and was impaired in display characteristics.

The layered type liquid crystal element of Comparative Example 1 was scratched in the display region of the resin substrate and thus showed deteriorated display quality. The scratch is presumed to have occurred in the process of producing the element.

### [20-12] Comparative Example 2

In Comparative Example 2, a layered type liquid crystal element, in which three liquid crystal cells for red, green and blue displays were layered in this order, was produced as described below.

The layered type liquid crystal element of Comparative Example 2 was produced in the same manner as in Experimental Example 2 except the following.

In Comparative Example 2, each liquid crystal cell of the layered type liquid crystal element was prepared using a substrate module SMi instead of the substrate module SMa.

The substrate module SMi has a film substrate made of polycarbonate (PC) The substrate is square and measures 10 cm by 10 cm and 140 μm in thickness. Only a 150 nm-thick transparent conductive film composed of IZO was formed on the substrate of substrate module SMi. The IZO film was formed by a sputtering method.

Using the substrate module SMi, the layered type liquid crystal element was prepared by carrying out the same step of patterning the IZO film on the substrate to form an electrode and the same subsequent step as in Experimental Example 2. In Comparative Example 2, each of the belt-like electrode portions was 180 μm wide and was spaced away by 20 μm from the neighboring electrode portion.

In the layered type liquid crystal element prepared in Comparative Example 2, breaking occurred in seven belt-like electrode portions among 500 in total.

The layered type liquid crystal element of Comparative Example 2 was investigated as to the contrast in the same manner as in Experimental Example 2. The layered type liquid crystal element of Comparative Example 2 exhibited an initial contrast of 5.9. However, after standing for 100 hours in a high temperature/high humidity environment (70° C./80% RH), the layered type liquid crystal element of Comparative Example 2 was reduced in contrast to 4.2 and was impaired in display characteristics.

In the layered type liquid crystal element of Comparative Example 2, scratch was found in the display region of the resin substrate and thus a deteriorated display quality was shown. The element is presumed to have become scratched in the process of producing the element.

### [20-13] Comparative Example 3

In Comparative Example 3, a layered type liquid crystal element, in which three liquid crystal cells for red, green and blue displays were layered in this order, was produced as described below.

The layered type liquid crystal element of Comparative Example 3 was produced in the same manner as in Experimental Example 2 except the following.

In Comparative Example 3, each liquid crystal cell of the layered type liquid crystal element was prepared using a substrate module SMj instead of the substrate module SMa.

The substrate module SMj has a substrate made of glass. The substrate is square and measures 10 cm by 10 cm and 0.7 mm in thickness. Only a 150 nm-thick transparent conductive film made of ITO was formed on the substrate. The ITO film was formed by a sputtering method.

Using the substrate module SMj, the layered type liquid crystal element was prepared by carrying out the similar step of patterning the ITO film on the substrate to form an electrode and the same subsequent step as in Experimental Example 2. In Comparative Example 3, each of the belt-like electrode portions was 180 μm wide and was spaced away by 20 μm from the neighboring electrode portion.

In the layered type liquid crystal element prepared in Comparative Example 3, no break was detected in a total of 500 belt-like electrode portions.

The layered type liquid crystal element of Comparative Example 3 was investigated as to the contrast in the same manner as in Experimental Example 2. The layered type liquid crystal element of Comparative Example 3 exhibited a contrast of 5.0. Even after standing for 100 hours in a high temperature/high humidity environment (70° C./80% RH), the layered type liquid crystal element of Comparative Example 3 showed no lowered contrast. But in the layered type liquid crystal element of Comparative Example 3, displayed images of the same pixel in each liquid crystal cell were shifted to each other when a visual point was moved, because of the relatively large thickness of the substrate.

[20-14] Table 1 shows the summarized results obtained in Experimental Examples 1 to 10 and Comparative Examples 1 to 3.

TABLE 1

| | | | | Gas barrier |
|---|---|---|---|---|
| | Structure | Substrate | Electrode | layer |
| Exp. Ex. 1 | LC/S. Layer | PC/140 μm | IZO/150 nm | SiOx/100 nm |
| Exp. Ex. 2 | LC/Layered | PC/140 μm | IZO/150 nm | SiOx/100 nm |
| Exp. Ex. 3 | LC/Layered | PC/100 μm | IZO/100 nm | SiOx/50 nm |
| Exp. Ex. 4 | LC/Layered | PC/150 μm | IZO/120 nm | SiOx/100 nm |
| Exp. Ex. 5 | LC/Layered | PC/100 μm | IZO/140 nm | SiOx/80 nm |
| Exp. Ex. 6 | LC/Layered | PC/200 μm | IZO/150 nm | SiOx/150 nm |
| Exp. Ex. 7 | LC/Layered | PC/130 μm | IZO/180 nm | SiOx/30 nm |
| Exp. Ex. 8 | LC/Layered | PC/120 μm | IZO/130 nm | Al₂O₃/100 nm |
| Exp. Ex. 9 | EL/S. layer | PC/150 μm | IZO/120 nm | SiOx/100 nm |
| Exp. Ex. | EL/S. layer | PC/150 μm | IZO/120 nm | SiOx/100 nm |
| 10 | | | | |
| Comp. Ex. | LC/Layered | PC/140 μm | ITO/150 nm | None |
| 1 | | | | |
| Comp. Ex. | LC/Layered | Pc/140 μm | IZO/150 nm | None |
| 2 | | | | |
| Comp. Ex. | LC/Layered | Glass/0.7 mm | ITO/150 nm | None |
| 3 | | | | |

| | | | | Number of | |
|---|---|---|---|---|---|
| | Hard coat | Anchor | Under-coat | broken | |
| | layer | layer | layer | portions | Contrast |
| Exp. Ex. 1 | Epoxy/2 μm | None | None | 1 | 8.1→8.1 |
| Exp. Ex. 2 | Epoxy/2 μm | None | None | 3 | 6.0→6.0 |
| Exp. Ex. 3 | Epoxy/2 μm | None | None | 2 | 6.6→6.6 |
| Exp. Ex. 4 | Epoxy/2 μm | None | Ureth/3 μm | 0 | 6.3→6.3 |
| Exp. Ex. 5 | Epoxy/2 μm | None | Ureth/3 μm | 0 | 6.5→6.5 |
| Exp. Ex. 6 | Epoxy/2 μm | Ureth/ | Ureth/3 μm | 0 | 5.8→5.8 |
| | | 2 μm | | | |
| Exp. Ex. 7 | Acryl/3 μm | Ureth/ | Ureth/1 μm | 0 | 6.4→6.4 |
| | | 2 μm | | | |
| Exp. Ex. 8 | Epoxy/2 μm | Acryl/ | Ureth/3 μm | 0 | 6.2→6.2 |
| | | 1 μm | | | |
| Exp. Ex. 9 | Epoxy/2 μm | None | Ureth/3 μm | 0 | — |
| Exp. Ex. | Epoxy/2 μm | None | Ureth/3 μm | 0 | — |
| 10 | | | | | |
| Comp. Ex. | None | None | None | 20 | 5.8→3.9 |
| 1 | | | | | |
| Comp. Ex. | None | None | None | 7 | 5.9→4.2 |
| 2 | | | | | |
| Comp. Ex. | None | None | None | 0 | 5.0→5.0 |
| 3 | | | | | |

Note: Exp. = Experimental. Ex. = Example. Comp. = Comparative. LC = liquid crystal element. S. layer = single layer type. Layered = layered type. Ureth = urethane resin.

The followings are understood from Table 1.

Even after left to stand in a high temperature and high humidity environment for a long time, the liquid crystal elements of Experimental Examples 1 to 8, in which the gas barrier layer is formed on the resin substrate, underwent no change in contrast. It is clear from the above that these liquid crystal elements of Experimental Examples 1 to 8 can suppress the deterioration of the liquid crystal layer (liquid crystal) due to water and oxygen, compared with the liquid crystal elements of Comparative Examples 1 and 2 in which no gas barrier layer is formed on the resin substrate.

The organic electro-luminescence elements of Experimental Examples 9 and 10 having the gas barrier layer can suppress the impairment of organic luminescent film due to water and oxygen because a dark spot and the like do not occur even after driving for 100 hours.

By comparing the layered type liquid crystal element of Experimental Example 3 having the IZO electrode directly formed on the resin substrate, with the layered type liquid crystal element of Comparative Example 1 having the ITO electrode directly formed on the resin substrate, it is found out that, although the electrode of Experimental Example 3 is thinner than that of Comparative Example 1, broken belt-like electrode portions in the former electrode were far fewer in the number than those in the latter. Accordingly, it is understood that the employment of IZO as the material for electrode can preclude the electrode from suffering damage such as cracks during, e.g., the production of the element, compared with the case where ITO is used as the material for the electrode.

No break was detected among the belt-like electrode portions in the layered type liquid crystal elements of Experimental Examples 4 to 8 and in the organic electro-luminescence elements of Experimental Examples 9 and 10 in all of which the undercoat layer is formed between the IZO electrode and the resin substrate. It is understood from the above that the undercoat layer can increase the adhesion of the electrode to the resin substrate and can prevent the electrode from suffering damage such as cracks during the production of the element.

The resin substrates were not marred in the liquid crystal elements of Experimental Examples 1 to 8 in which the hard coat layer is formed on the resin substrate, whereas the resin substrates were marred in the layered type liquid crystal elements of Comparative Examples 1 and 2 in which the hard coat layer is not formed on the resin substrate. This clearly shows that the hard coat layer can prevent the resin substrate from being marred.

It is further understood that the liquid crystal elements of Experimental Examples 1 to 8 in which the IZO electrode is formed on the resin substrate can attain a contrast which is as high as or higher than that of the layered type liquid crystal element of Comparative Example 1 in which the ITO electrode is formed on the resin substrate.

It is also understood that the liquid crystal elements of Experimental Examples 1 to 8 in which at least two of the gas barrier layer, hard coat layer, anchor layer and undercoat layer as well as the electrode are formed on the resin substrate can attain a contrast which is as high as or higher than that of the the layered type liquid crystal elements of Comparative Examples 1 and 2 in which only the electrode is formed on the resin substrate.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A display element comprising:
a display layer; and
a member which holds or carries said display layer, said member comprising:
a resin substrate;
an anchor layer formed on said resin substrate;
a gas barrier layer formed on said anchor layer, said gas barrier layer being made of SiOₓ (0<x≦2) or Al₂O₃; and
a transparent electrode formed on said gas barrier layer, said transparent electrode being made of an amorphous oxide comprising indium (In), zinc (Zn) and oxygen (O) as essential constituent elements.

2. A display element according to claim 1, wherein said member further comprises an undercoat layer between said resin substrate and said transparent electrode.

3. A display element according to claim 1, wherein thickness of said gas barrier layer is in a range from 1 nm to 200 nm.

4. A display element according to claim 1, wherein thickness of said resin substrate is in a range from 50 μm to 250 μm.

5. A display element according to claim 1, wherein said amorphous oxide further contains at least one kind of halogen.

6. A display element according to claim 1, wherein said display layer is a liquid crystal layer including a liquid crystal.

7. A display element according to claim 1, wherein said display layer is an organic luminescent film.

8. A display element comprising:
a display layer; and
a member which holds or carries said display layer, said member comprising:
a resin substrate having a first surface and a second surface opposing said first surface;
a gas barrier layer formed on said first surface of said resin substrate, said gas barrier layer being made of SiOₓ (0<x≦2) or Al₂O₃; and
a transparent electrode formed on said second surface of said resin substrate, said transparent electrode being made of an amorphous oxide comprising indium (In), zinc (Zn) and oxygen (O) as essential constituent elements.

9. A display element according to claim 8, wherein said member further comprises an anchor layer between said resin substrate and said gas barrier layer.

10. A display element according to claim 8, wherein said member further comprises an undercoat layer between said resin substrate and said transparent electrode.

11. A display element according to claim 8, wherein thickness of said gas barrier layer is in a range from 1 nm to 200 nm.

12. A display element according to claim 8, wherein thickness of said resin substrate is in a range from 50 μm to 250 μm.

13. A display element according to claim 8, wherein said amorphous oxide further contains at least one kind of halogen.

14. A display element according to claim 8, wherein said display layer is a liquid crystal layer including a liquid crystal.

15. A display element according to claim 8, wherein said display layer is an organic luminescent film.

16. A display element comprising:
a display layer; and
a member which holds or carries said display layer, said member comprising:
a resin substrate having a first surface and a second surface opposing said first surface;
a gas barrier layer formed on said first surface of said resin substrate, said gas barrier layer being made of SiOₓ (0<x≦2) or Al₂O₃;
a transparent electrode formed on said gas barrier layer, said transparent electrode being made of an amorphous oxide comprising indium (In), zinc (Zn) and oxygen (O) as essential constituent elements; and
a hard coat layer formed on said second surface of said resin substrate.

17. A display element according to claim 16, wherein said member further comprises an anchor layer between said resin substrate and said gas barrier layer.

18. A display element according to claim 16, wherein said member further comprises an undercoat layer between said resin substrate and said transparent electrode.

19. A display element according to claim 16, wherein thickness of said gas barrier layer is in a range from 1 nm to 200 nm.

20. A display element according to claim 16, wherein thickness of said resin substrate is in a range from 50 μm to 250 μm.

21. A display element according to claim 16, wherein said amorphous oxide further contains at least one kind of halogen.

22. A display element according to claim 16, wherein said display layer is a liquid crystal layer including a liquid crystal.

23. A display element according to claim 16, wherein said display layer is an organic luminescent film.

24. A display element comprising:
a display layer; and
a member which holds or carries said display layer, said member comprising:
a resin substrate having a first surface and a second surface opposing said first surface;
a gas barrier layer formed on said first surface of said resin substrate, said gas barrier layer being made of SiOₓ (0<x≦2) or Al₂O₃;
a hard coat layer formed on said gas barrier layer; and
a transparent electrode formed on said second surface of said resin substrate, said transparent electrode being made of an amorphous oxide comprising indium (In), zinc (Zn) and oxygen (O) as essential constituent elements.

25. A display element according to claim 24, wherein said member further comprises an anchor layer between said resin substrate and said gas barrier layer.

26. A display element according to claim 24, wherein said member further comprises an undercoat layer between said resin substrate and said transparent electrode.

27. A display element according to claim 24, wherein thickness of said gas barrier layer is in a range from 1 nm to 200 nm.

28. A display element according to claim 24, wherein thickness of said resin substrate is in a range from 50 μm to 250 μm.

29. A display element according to claim 24, wherein said amorphous oxide further contains at least one kind of halogen.

30. A display element according to claim 24, wherein said display layer is a liquid crystal layer including a liquid crystal.

31. A display element according to claim 24, wherein said display layer is an organic luminescent film.

32. A layered type display element comprising:
a plurality of display layers layered together; and
a member which holds or carries at least one of said display layers, said member comprising:
a resin substrate;
an anchor layer formed on said resin substrate;
a gas barrier layer formed on said anchor layer, said gas barrier layer being made of SiOₓ (0<x≦2) or Al₂O₃; and
a transparent electrode formed on said gas barrier layer, said transparent electrode being made of an amorphous oxide comprising indium (In), zinc (Zn) and oxygen (O) as essential constituent elements.

33. A layered type display element according to claim 32, wherein said amorphous oxide further contains at least one kind of halogen.

34. A layered type display element according to claim 32, wherein said display layer is a liquid crystal layer including a liquid crystal.

35. A layered type display element according to claim 32, wherein said display layer is an organic luminescent film.

36. A layered type display element comprising:
a plurality of display layers layered together; and
a member which holds or carries at least one of said display layers, said member comprising:
a resin substrate having a first surface and a second surface opposing said first surface;
a gas barrier layer formed on said first surface of said resin substrate, said gas barrier layer being made of SiOₓ (0<x≦2) or Al₂O₃; and
a transparent electrode formed on said second surface of said resin substrate, said transparent electrode being made of an amorphous oxide comprising indium (In), zinc (Zn) and oxygen (O) as essential constituent elements.

37. A layered type display element according to claim 36, wherein said amorphous oxide further contains at least one kind of halogen.

38. A layered type display element according to claim 36, wherein said display layer is a liquid crystal layer including a liquid crystal.

39. A layered type display element according to claim 36, wherein said display layer is an organic luminescent film.

40. A layered type display element comprising:
a plurality of display layers layered together; and
a member which holds or carries at least one of said display layers, said member comprising:
a resin substrate having a first surface and a second surface opposing said first surface;
a gas barrier layer formed on said first surface of said resin substrate, said gas barrier layer being made of SiOₓ (0<x≦2) or Al₂O₃;
a transparent electrode formed on said gas barrier layer, said transparent electrode being made of an amorphous oxide comprising indium (In), zinc (Zn) and oxygen (O) as essential constituent elements; and
a hard coat layer formed on said second surface of said resin substrate.

41. A layered type display element according to claim 40, wherein said amorphous oxide further contains at least one kind of halogen.

42. A layered type display element according to claim 40, wherein said display layer is a liquid crystal layer including a liquid crystal.

43. A layered type display element according to claim 40, wherein said display layer is an organic luminescent film.

44. A layered type display element comprising:
a plurality of display layers layered together; and
a member which holds or carries at least one of said display layers, said member comprising:
a resin substrate having a first surface and a second surface opposing said first surface;
a gas barrier layer formed on said first surface of said resin substrate, said gas barrier layer being made of SiOₓ (0<x≦2) or Al₂O₃;
a hard coat layer formed on said gas barrier layer; and
a transparent electrode formed on said second surface of said resin substrate, said transparent electrode being made of an amorphous oxide comprising indium (In), zinc (Zn) and oxygen (O) as essential constituent elements.

45. A layered type display element according to claim 44, wherein said amorphous oxide further contains at least one kind of halogen.

46. A layered type display element according to claim 44, wherein said display layer is a liquid crystal layer including a liquid crystal.

47. A layered type display element according to claim 44, wherein said display layer is an organic luminescent film.
